(19) United States
(12) Patent Application Publication
(10) Pub. No.: US 2026/0197993 A1
(43) Pub. Date: Jul. 9, 2026

(54) INTEGRATED CIRCUIT DEVICE

(71) Applicant: SAMSUNG ELECTRONICS CO., LTD., SUWON-SI (KR)

(72) Inventors: Sohyeon BAE, Suwon-si (KR); Jooncheol KIM, Suwon-si (KR); Gyuhyun KIL, Suwon-si (KR); Sanghoon MIN, Suwon-si (KR); Hoin RYU, Suwon-si (KR); Jinhee CHUN, Suwon si (KR)

(73) Assignee: SAMSUNG ELECTRONICS CO., LTD., SUWON-SI (KR)

(21) Appl. No.: 19/288,197

(22) Filed: Aug. 1, 2025

(30) Foreign Application Priority Data
Jan. 3, 2025 (KR) 10-2025-0001179

(51) Int. Cl. H10B 12/00

(52) U.S. Cl. CPC H10B 12/482; H10B 12/09; H10B 12/485; H10B 12/50

(57) ABSTRACT

An integrated circuit device includes a substrate having a cell array area, first and second bit lines arranged over the substrate in the cell array area so as to be spaced apart from each other in a first horizontal direction and extending in a second horizontal direction perpendicular to the first horizontal direction, and a bit line pad arranged over the substrate in a first edge portion, in the second horizontal direction, of the cell array area and integrally connected to the first bit line out of the first and second bit lines, the bit line pad having a width greater in the first horizontal direction than a width of each of the first and second bit lines, wherein the second bit line includes a bit line extension portion facing the bit line pad in the first horizontal direction in the first edge portion.

### CROSS-REFERENCE TO RELATED APPLICATION

This application is based on and claims priority under 35 U.S.C. § 119 to Korean Patent Application No. 10-2025-0001179, filed on Jan. 3, 2025, in the Korean Intellectual Property Office, the disclosure of which is incorporated by reference herein in its entirety.

### BACKGROUND

The inventive concept relates to an integrated circuit device, and more particularly, to an integrated circuit device including a plurality of bit lines.

Due to the advancement of electronics technology, integrated circuit devices have been rapidly down-scaled in recent years, and feature sizes of integrated circuit devices have been micronized. Therefore, it is necessary to develop structures capable of securing the reliability of unit devices arranged in cell array areas.

### SUMMARY

The inventive concept provides an integrated circuit device that has a structure capable providing reliability by preventing unintended short-circuits between a plurality of bit lines in a cell array area and other conductive regions adjacent to the plurality of bit lines.

According to an aspect of the inventive concept, there is provided an integrated circuit device including a substrate having a cell array area, a first bit line and a second bit line, which are arranged over the substrate in the cell array area so as to be spaced apart from each other in a first horizontal direction, the first bit line and the second bit line extending in a second horizontal direction that is perpendicular to the first horizontal direction, and a bit line pad arranged over the substrate in a first edge portion, in the second horizontal direction, of the cell array area and integrally connected to only the first bit line out of the first bit line and the second bit line, the bit line pad having a width that is greater in the first horizontal direction than a width of each of the first bit line and the second bit line, wherein the second bit line includes a bit line extension portion facing the bit line pad in the first horizontal direction in the first edge portion of the cell array area.

According to another aspect of the inventive concept, there is provided an integrated circuit device including a substrate that has a cell array area and a core area surrounding the cell array area, a plurality of bit lines, which are arranged over the substrate in the cell array area so as to be spaced apart from each other in a first horizontal direction, the plurality of bit lines extending in a second horizontal direction that is perpendicular to the first horizontal direction, and a plurality of bit line pads arranged over the substrate in the cell array area and respectively and integrally connected to the plurality of bit lines, wherein the plurality of bit line pads include a plurality of first bit line pads that are arranged in a first edge portion, which is adjacent to the core area in the second horizontal direction, of the cell array area and respectively and integrally connected to only a plurality of first bit lines selected from among the plurality of bit lines every other bit line in the first horizontal direction, each of the plurality of first bit line pads having a width that is greater in the first horizontal direction than a width of each of the plurality of bit lines, and a plurality of second bit lines except for the plurality of first bit lines from among the plurality of bit lines each include a bit line extension portion facing, in the first horizontal direction, two adjacent first bit line pads from among the plurality of first bit line pads in the first edge portion of the cell array area.

According to another aspect of the inventive concept, there is provided an integrated circuit device including a substrate, which has a cell array area, a peripheral circuit area including a core area adjacent to the cell array area, and an interface area between the cell array area and the core area, a plurality of bit lines arranged over the substrate in the cell array so as to be spaced apart from each other in a first horizontal direction, the plurality of bit lines extending in a second horizontal direction that is perpendicular to the first horizontal direction, a plurality of bit line pads respectively and integrally connected to only a plurality of first bit lines arranged over the substrate in a first edge portion, which is adjacent to the core area, of the cell array area, the plurality of first bit lines being selected from among the plurality of bit lines every other bit line in the first horizontal direction, a plurality of buried contacts arranged in a line in the second horizontal direction between each of the plurality of bit lines, and a plurality of dummy buried contacts arranged in a line in the second horizontal direction between each of the plurality of bit line pads, wherein each of the plurality of bit line pads has a width that is greater in the first horizontal direction than a width of each of the plurality of bit lines, a plurality of second bit lines except for the plurality of first bit lines from among the plurality of bit lines each include a bit line extension portion arranged between two adjacent bit line pads from among the plurality of bit line pads in the first edge portion of the cell array area, the plurality of buried contacts and the plurality of dummy buried contacts are arranged at equal pitches in the second horizontal direction, and the plurality of buried contacts and the plurality of dummy buried contacts include a same material.

### BRIEF DESCRIPTION OF THE DRAWINGS

Embodiments will be more clearly understood from the following detailed description taken in conjunction with the accompanying drawings in which:

FIG. 1 is a block diagram illustrating an example of a configuration of an integrated circuit device according to embodiments;

FIG. 2 is a diagram illustrating an example of an arrangement configuration in the integrated circuit device shown in FIG. 1;

FIG. 3 is a schematic planar layout illustrating main components of a memory cell array in a cell array area shown in FIG. 2;

FIG. 4 is an enlarged plan view illustrating some components in a region EX2 of FIG. 2;

FIG. 5A is a cross-sectional view of the integrated circuit device of FIG. 3, taken along a line X1-X1′ of FIG. 3;

FIG. 5B is a cross-sectional view of the integrated circuit device of FIG. 3, taken along a line X2-X2′ of FIG. 3;

FIG. 5C is a cross-sectional view of the integrated circuit device of FIG. 4, taken along a line X3-X3′ of FIG. 4;

FIG. 5D is a cross-sectional view of the integrated circuit device of FIG. 4, taken along a line Y1-Y1′ of FIG. 4 and an extension line thereof;

FIG. 5E is a cross-sectional view of the integrated circuit device of FIG. 4, taken along a line Y2-Y2′ of FIG. 4 and an extension line thereof;

FIGS. 6 and 7 are cross-sectional views respectively illustrating integrated circuit devices according to some embodiments;

FIG. 8A is a plan view illustrating an integrated circuit device according to some embodiments;

FIG. 8B is a cross-sectional view of the integrated circuit device of FIG. 8A, taken along a line Y1-Y1′ of FIG. 8A;

FIG. 8C is a cross-sectional view of the integrated circuit device of FIG. 8A, taken along a line Y2-Y2′ of FIG. 8A;

FIG. 9 and FIG. 10 are cross-sectional views respectively illustrating integrated circuit devices according to some embodiments; and

FIG. 11A, FIG. 11B, FIG. 11C, FIG. 12A, FIG. 12B, FIG. 13A, FIG. 13B, FIG. 13C, FIG. 14A, FIG. 14B, FIG. 14C, FIG. 15A, FIG. 15B, FIG. 15C, FIG. 15D, FIG. 15E, FIG. 15F, FIG. 16A, FIG. 16B, FIG. 16C, FIG. 16D, FIG. 17A, FIG. 17B, FIG. 17C, FIG. 18A, FIG. 18B, FIG. 18C, FIG. 19A, FIG. 19B, FIG. 20A, FIG. 20B, FIG. 20C, FIG. 20D, and FIG. 20E, are diagrams respectively illustrating a sequence of processes of a method of fabricating an integrated circuit device, according to embodiments, and in particular, FIGS. 15A, 16A, 17A, 18A, and 20A are plan views of a region corresponding to the region EX2 of FIG. 2, according to the sequence of processes, FIGS. 11A, 12A, 13A, 14A, 15B, 16B, 18B, 19A, and 20B are cross-sectional views of a region corresponding to a cross-section taken along the line X1-X1′ of FIG. 4, according to the sequence of processes, FIGS. 11B, 12B, 13B, 14B, 15C, 16C, and 17B are cross-sectional views of a region corresponding to a cross-section taken along the line X2-X2′ of FIG. 4, according to the sequence of processes, FIGS. 15D, 16D, 17C, 18C, 19B, and 20C are cross-sectional views of a region corresponding to a cross-section taken along the line X3-X3′ of FIG. 4, according to the sequence of processes, FIGS. 11C, 13C, 14C, 15E, and 20D are cross-sectional views of a region corresponding to a cross-section taken along the line Y1-Y1′ of FIG. 4, according to the sequence of processes, and FIGS. 15F and 20E are cross-sectional views of a region corresponding to a cross-section taken along the line Y2-Y2′ of FIG. 4, according to the sequence of processes.

### DETAILED DESCRIPTION OF THE EMBODIMENTS

Hereinafter, embodiments of the inventive concept will be described in detail with reference to the accompanying drawings. Like components are denoted by like reference numerals throughout the specification, and repeated descriptions thereof are omitted.

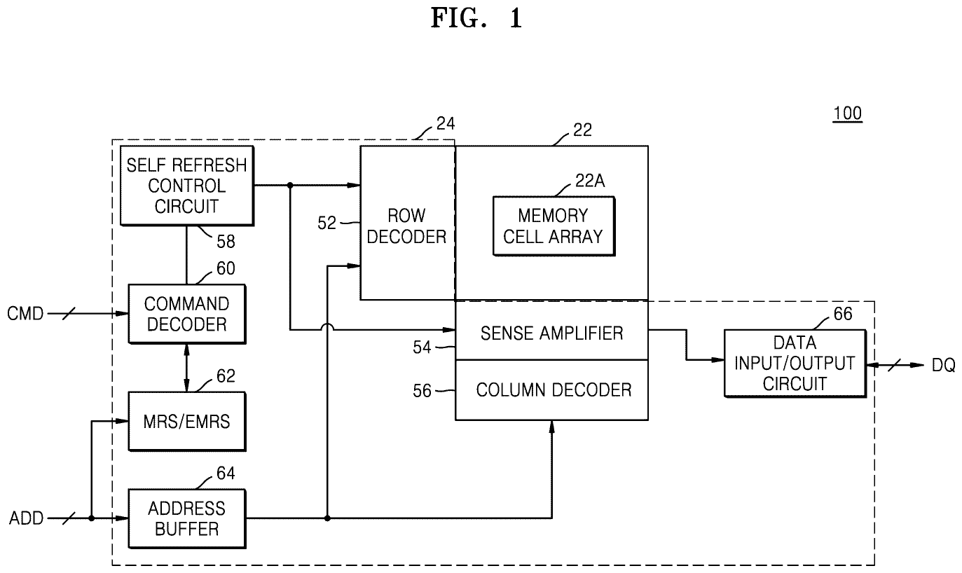

FIG. 1 is a block diagram illustrating an example of a configuration of an integrated circuit device 100 according to embodiments.

Referring to FIG. 1, the integrated circuit device 100 includes a first area 22 and a second area 24. The first area 22 may include a memory cell area of a dynamic random access memory (DRAM) device, and the second area 24 may include an area, in which peripheral circuits of the DRAM device are formed, and a core area (referred to as a “peripheral circuit area”, hereinafter). The first area 22 may include a memory cell array 22A. The second area 24 may include a row decoder 52, a sense amplifier 54, a column decoder 56, a self-refresh control circuit 58, a command decoder 60, a Mode Register Set/Extended Mode Register Set (MRS/EMRS) circuit 62, an address buffer 64, and a data input/output circuit 66. Peripheral circuits, such as an inverter chain and an input/output circuit, may be further formed in the second area 24 of FIG. 1.

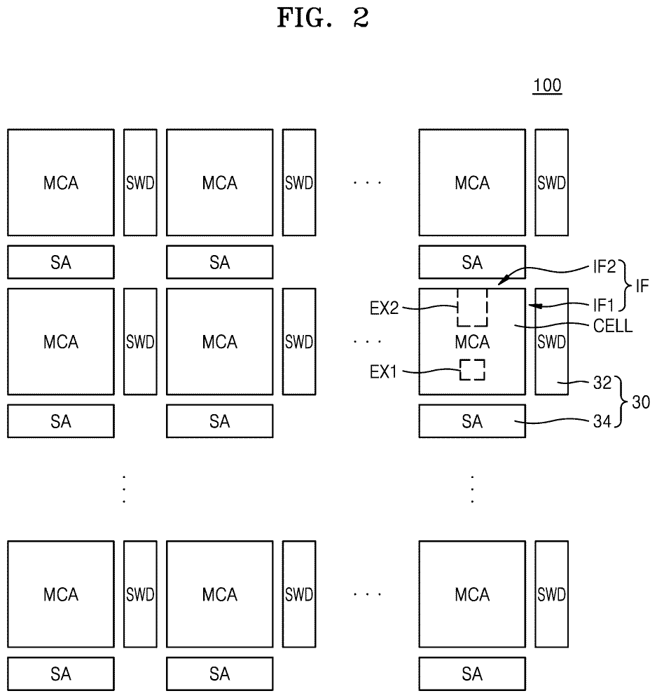

FIG. 2 is a diagram illustrating an example of an arrangement configuration in the integrated circuit device 100 shown in FIG. 1.

Referring to FIGS. 1 and 2, the first area 22 of the integrated circuit device 100 may include a plurality of cell array areas CELL and a core area 30 arranged adjacent to each of the plurality of cell array areas CELL. The plurality of cell array areas CELL may be a portion of the first area 22 shown in FIG. 1. The core area 30 may be a portion of the second area 24 shown in FIG. 1. The core area 30 may include a sub-word line driver area 32, which is adjacent to one side of the cell array area CELL, and a sense amplifier area 34, which is adjacent to another side of the cell array area CELL. In FIG. 2, the term “MCA” denotes a memory cell array arranged in the cell array area CELL and may correspond to the memory cell array 22A shown in FIG. 1. In FIG. 2, the term “SWD” denotes a sub-word line driver block arranged in the core area 30, and the sub-word line driver area 32 may also be referred to as a sub-word line driver area SWD. The term “SA” denotes a sense amplifier block arranged in the core area 30, and the sense amplifier area 34 may also be referred to as a sense amplifier area SA.

An interface area IF may be arranged between the cell array area CELL and the core area 30. The interface area IF may include a first interface area IF1, which is arranged between the cell array area CELL and the sub-word line driver area SWD, and a second interface area IF2, which is arranged between the cell array area CELL and the sense amplifier area SA.

The sub-word line driver area SWD may include circuits for driving a plurality of word lines arranged in the cell array area CELL. The sense amplifier area SA may include a sense amplifier for sensing and amplifying signals of a plurality of bit lines arranged in the cell array area CELL.

A conjunction block may be arranged at an intersection point between the sub-word line driver area SWD and the sense amplifier area SA in the core area 30. Power supply drivers and ground drivers for driving a bit line sense amplifier may be arranged in the conjunction block.

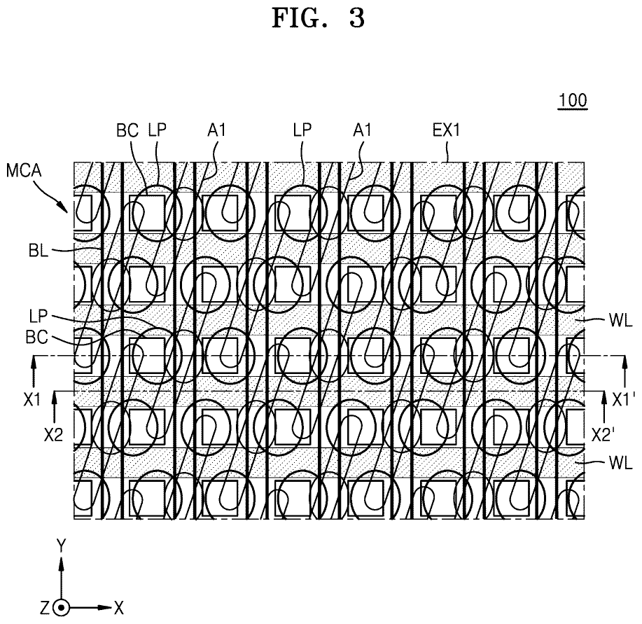

FIG. 3 is a schematic planar layout illustrating main components of the memory cell array MCA in the cell array area CELL shown in FIG. 2. The planar layout shown in FIG. 3 may correspond to a region EX1 of FIG. 2.

Referring to FIG. 3, the memory cell array MCA may include a plurality of cell active regions A1. Each of the plurality of cell active regions A1 may be arranged to have a major axis in an oblique direction with respect to a first horizontal direction (an X direction) and a second horizontal direction (a Y direction), which are perpendicular to each other. A plurality of word lines WL may extend in the first horizontal direction (the X direction) across the plurality of cell active regions A1 so as to be parallel to each other. A plurality of bit lines BL may extend in the second horizontal direction (the Y direction) over the plurality of word lines WL so as to be parallel to each other. The first horizontal direction (the X direction) and the second horizontal direction (the Y direction) may be directions intersecting with each other. For example, the first horizontal direction (the X direction) and the second horizontal direction (the Y direction) may be directions orthogonal to each other.

Each of the plurality of bit lines BL may be connected to each of the plurality of cell active regions A1 via a direct contact DC. A plurality of buried contacts BC may be arranged between two adjacent bit lines BL from among the plurality of bit lines BL. The plurality of buried contacts BC may be arranged in a line in the first horizontal direction (the X direction) and the second horizontal direction (the Y direction). A plurality of conductive landing pads LP may be respectively arranged on the plurality of buried contacts BC. Each of the plurality of buried contacts BC and each of the plurality of conductive landing pads LP may connect a lower electrode (not shown) of a capacitor, which is formed over each of the plurality of bit lines BL, to a cell active region A1. Each of the plurality of conductive landing pads LP may be arranged to partially overlap a buried contact BC.

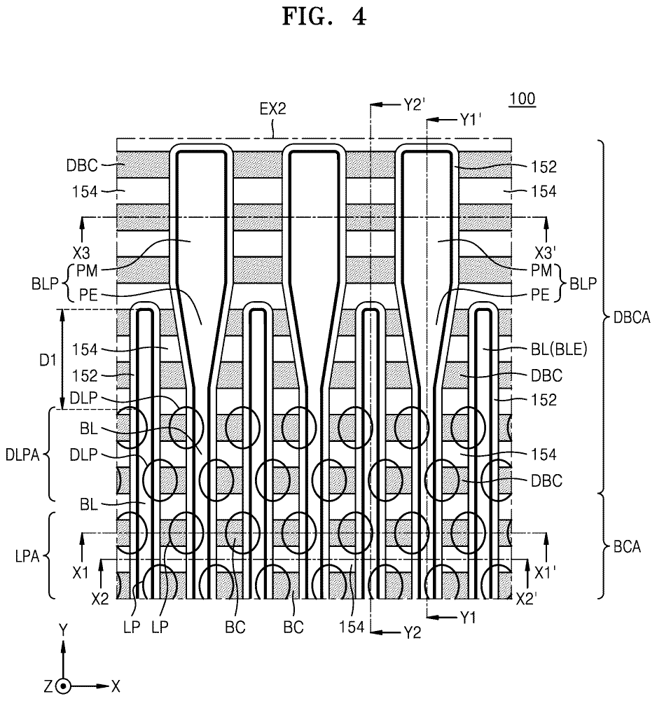

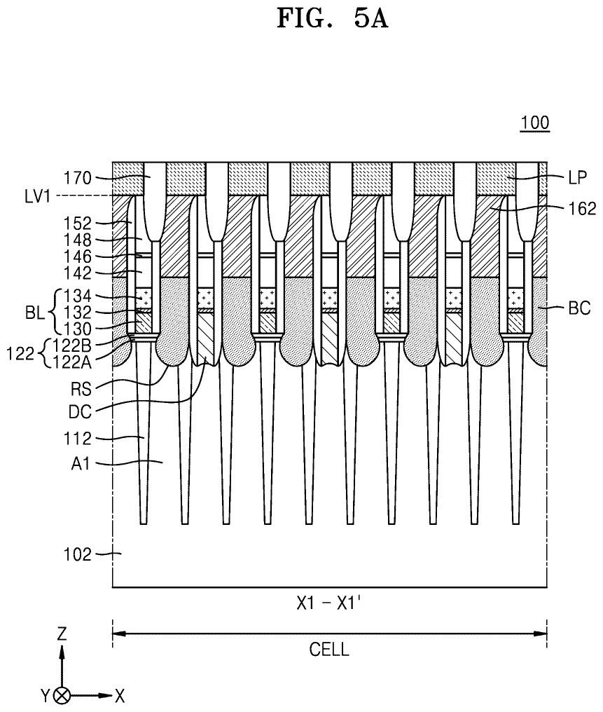

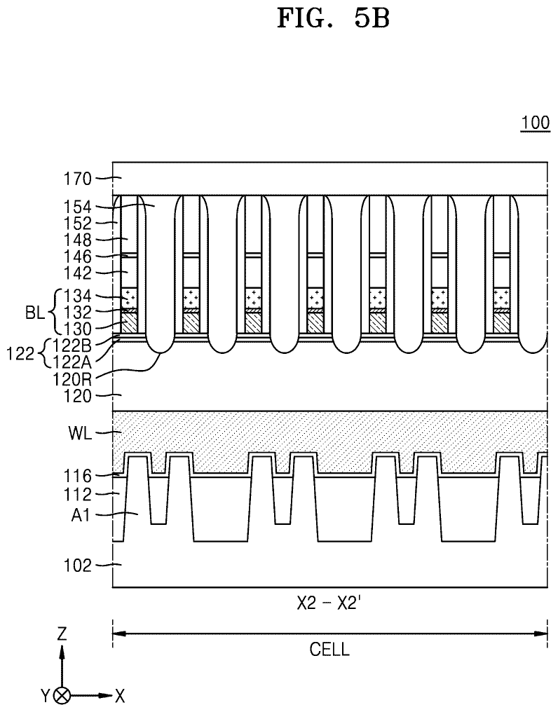

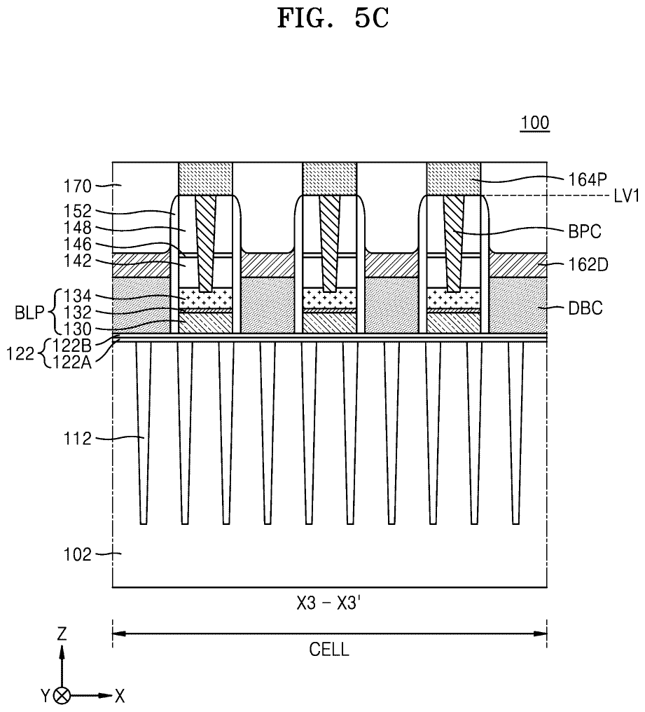

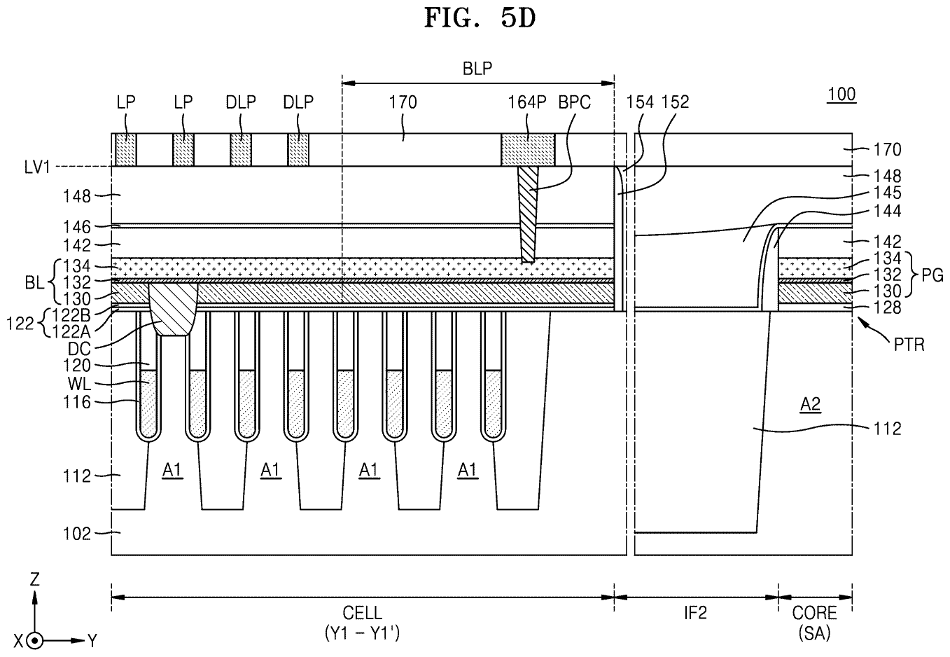

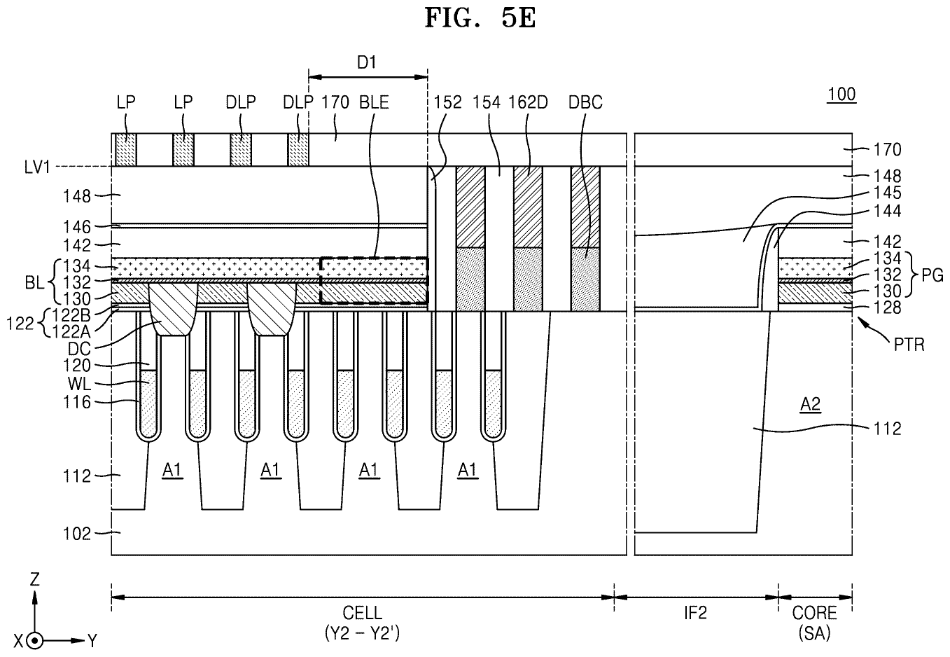

FIG. 4 is an enlarged plan view illustrating some components in a region EX2 of FIG. 2. FIGS. 5A and 5B are each a cross-sectional view of a portion of the cell array area CELL. FIG. 5A illustrates a configuration of the integrated circuit device 100, taken along a line X1-X1′ of FIG. 3, and FIG. 5B illustrates a configuration of the integrated circuit device 100, taken along a line X2-X2′ of FIG. 3. FIG. 5C is a cross-sectional view of the integrated circuit device 100, taken along a line X3-X3′ of FIG. 4, FIG. 5D is a cross-sectional view of the integrated circuit device 100, taken along a line Y1-Y1′ of FIG. 4, and FIG. 5E is a cross-sectional view of the integrated circuit device 100, taken along a line Y2-Y2′ of FIG. 4. The cross-sectional configuration of FIG. 5A may be the same as a cross-sectional configuration taken along the line X1-X1′ of FIG. 4. The cross-sectional configuration of FIG. 5B may be the same as a cross-sectional configuration taken along the line X2-X2′ of FIG. 4.

The integrated circuit device 100 is described in more detail with reference to FIGS. 3, 4, and 5A to 5E. The integrated circuit device 100 may include a substrate 102. The substrate 102 may have a cell array area CELL, a peripheral circuit area including a core area CORE, and an interface area IF (see FIG. 4) arranged between the cell array area CELL and the core area CORE. The core area CORE may correspond to the core area 30 shown in FIG. 2. The core area CORE may have a sub-word line driver area SWD, which is adjacent to the cell array area CELL in the first horizontal direction (the X direction), and a sense amplifier area SA, which is adjacent to the cell array area CELL in the second horizontal direction (the Y direction). The interface area IF may include a first interface area IF1, which is arranged between the cell array area CELL and the sub-word line driver area SWD, and a second interface area IF2, which is arranged between the cell array area CELL and the sense amplifier area SA.

The substrate 102 may include silicon, for example, single-crystal silicon, polycrystalline silicon, or amorphous silicon. In some embodiments, the substrate 102 may include at least one selected from Ge, SiGe, SiC, GaAs, InAs, and InP. In some embodiments, the substrate 102 may include a conductive region, for example, an impurity-doped well or an impurity-doped structure.

A device isolation film 112 may be arranged in the substrate 102. In the cell array area CELL, a plurality of cell active regions A1 may be defined in the substrate 102 by the device isolation film 112. In the peripheral circuit area including the core area CORE, a peripheral active region A2 may be defined in the substrate 102 by the device isolation film 112. In the device isolation film 112, portions arranged in the first and second interface areas IF1 and IF2 may have widths greater in the first horizontal direction (the X direction) and the second horizontal direction (the Y direction) than those of portions arranged in the cell array area CELL. The portions of the device isolation film 112, which are arranged in the first and second interface areas IF1 and IF2, may be arranged between the cell array area CELL and the core area CORE to isolate the cell array area CELL and the core area CORE from each other. The device isolation film 112 may have various depths depending on the positions thereof. The minimum depth of the device isolation film 112 may vary depending on the positions thereof. In some embodiments, the device isolation film 112 may include a silicon oxide film, a silicon nitride film, a silicon oxynitride film, or a combination thereof. For example, portions, which have relatively small widths in a horizontal direction (for example, the X direction or the Y direction), of the device isolation film 112 may each include only a silicon oxide film, and portions, which have relatively large widths in the horizontal direction, of the device isolation film 112 may each include a silicon oxide film and a silicon nitride film that is surrounded by the silicon oxide film.

As shown in FIGS. 5B, 5D, and 5E, the integrated circuit device 100 may include a plurality of word lines WL, which extend lengthwise in the first horizontal direction (the X direction) across the plurality of cell active regions A1 at a vertical level that is lower than a vertical level of the uppermost surface of the substrate 102 in the cell array area CELL. The plurality of word lines WL may extend parallel to each other. The lower surface and the sidewall of each of the plurality of word lines WL may be covered by a gate dielectric film 116, and the upper surface of each of the plurality of word lines WL may be covered by a buried insulating film 120. As shown in FIG. 5B, a plurality of recess spaces 120R may be formed in the upper surface of the buried insulating film 120.

In some embodiments, each of the plurality of word lines WL may include, but is not limited to, Ti, TiN, Ta, TaN, W, WN, TiSiN, WSiN, or a combination thereof. The gate dielectric film 116 may include a silicon oxide film, a silicon nitride film, a silicon oxynitride film, an oxide/nitride/oxide (ONO) film, or a high-k dielectric film having a dielectric constant higher than that of a silicon oxide film. For example, the gate dielectric film 116 may include, but is not limited to, HfO₂, Al₂O₃, HfAlO₃, Ta₂O₃, or TiO₂. The buried insulating film 120 may include, but is not limited to, a silicon oxide film, a silicon nitride film, a silicon oxynitride film, or a combination thereof.

A buffer film 122 may be formed on the substrate 102. The buffer film 122 may include a first insulating film 122A and a second insulating film 122B. Each of the first insulating film 122A and the second insulating film 122B may include, but is not limited to, a silicon oxide film, a silicon nitride film, a silicon oxynitride film, a metal oxide film, or a combination thereof.

A plurality of direct contacts DC may be formed on the substrate 102. Each of the plurality of direct contacts DC may be connected to a cell active region A1 selected from the plurality of cell active regions A1. The plurality of direct contacts DC may each include Si, Ge, W, WN, Co, Ni, Al, Mo, Ru, Ti, TiN, Ta, TaN, Cu, or a combination thereof.

A plurality of bit lines BL may extend lengthwise in the second horizontal direction (the Y direction) on or over the substrate 102 and the plurality of direct contacts DC. Each of the plurality of bit lines BL may be connected to the cell active region A1 via a direct contact DC. Each of the plurality of bit lines BL may include a lower conductive layer 130, an intermediate conductive layer 132, and an upper conductive layer 134, which are sequentially stacked in the stated order over the substrate 102. The lower conductive layer 130 may include doped polysilicon. Each of the intermediate conductive layer 132 and an upper conductive layer 134 may include TiN, TiSiN, W, tungsten silicide, or a combination thereof. In some embodiments, the intermediate conductive layer 132 may include TiN, TiSiN, or a combination thereof, and the upper conductive layer 134 may include W. Each of the plurality of bit lines BL may be covered by an insulating capping structure. The insulating capping structure may include an insulating capping layer 142, an insulating thin film 146, and an upper insulating capping layer 148. Each of the insulating capping layer 142, the insulating thin film 146, and the upper insulating capping layer 148 may include a silicon nitride film. The sidewalls of both the insulating capping structure and the plurality of bit lines BL may be respectively covered by a plurality of insulating spacers 152. The plurality of insulating spacers 152 may extend lengthwise in the second horizontal direction (the Y direction) so as to be parallel to the plurality of bit lines BL. Each of the plurality of insulating spacers 152 may include an oxide film, a nitride film, an air spacer, or a combination thereof. As used herein, the term “air” may refer to the atmosphere or to other gases that may be present during a fabrication process.

As shown in FIG. 5A, in the cell array area CELL, a plurality of buried contacts BC and a plurality of insulating fences 154 may be arranged between each of the plurality of bit lines BL. The plurality of buried contacts BC and the plurality of insulating fences 154 may be alternately arranged one-by-one in the second horizontal direction (the Y direction) between two adjacent bit lines BL from among the plurality of bit lines BL. Each of the plurality of buried contacts BC may be electrically connected to a cell active region A1 selected from the plurality of cell active regions A1. The plurality of insulating fences 154 may be arranged one-by-one between the plurality of buried contacts BC to respectively fill the plurality of recess spaces 120R formed in the upper surface of the buried insulating film 120. Both sidewalls of each of the plurality of buried contacts BC in terms of the second horizontal direction (the Y direction) may be respectively covered by the plurality of insulating fences 154. Each of the plurality of buried contacts BC may be spaced apart from a bit line BL in the first horizontal direction (the X direction) with an insulating spacer 152 therebetween. In some embodiments, the plurality of buried contacts BC may each include doped polysilicon, and the plurality of insulating fences 154 may each include a silicon nitride film.

As shown in FIGS. 4, 5C, and 5D, a plurality of bit line pads BLP may be arranged over the substrate 102 in the cell array area CELL. The plurality of bit line pads BLP may be respectively and integrally connected to the plurality of bit lines BL. The plurality of bit line pads BLP may be arranged in an edge portion of the cell array area CELL, the edge portion being adjacent to the core area CORE in the second horizontal direction (the Y direction). FIG. 4 illustrates portions of the plurality of bit lines BL and the plurality of bit line pads BLP, the portions being arranged in one edge portion (which may be referred to as a first edge portion, herein) out of two edge portions, in the second horizontal direction (the Y direction), of the cell array area CELL. Although not shown in FIG. 4, the plurality of bit lines BL may extend up to the other one edge portion (which may be referred to as a second edge portion, herein) out of the two edge portions, in the second horizontal direction (the Y direction), of the cell array area CELL, and also in the other one edge portion (the second edge portion), the plurality of bit lines BL and the plurality of bit line pads BLP may be arranged with planar shapes similar to those of FIG. 4. However, the plurality of bit line pads BLP may be respectively connected to the plurality of bit lines BL, and the plurality of bit line pads BLP in each of the first edge portion and the second edge portion may be respectively and integrally connected to only bit lines BL selected from among the plurality of bit lines BL every other bit line BL in the first horizontal direction (the X direction). Among the plurality of bit lines BL, a bit line BL not connected to a bit line pad BLP in the first edge portion shown in FIG. 4 may be integrally connected to a bit line pad BLP selected from among the plurality of bit line pads BLP in the second edge portion that is an opposite edge portion to the first edge portion in the second horizontal direction (the Y direction). Herein, the bit line pad BLP arranged in the first edge portion shown in FIG. 4 may be referred to as a first bit line pad, and the bit line pad BLP arranged in the second edge portion not shown in FIG. 4 may be referred to as a second bit line pad.

As shown in FIG. 4, each of the plurality of bit line pads BLP may have a width that is greater in the first horizontal direction (the X direction) than that of each of the plurality of bit lines BL. In the first edge portion of the cell array area CELL, among the plurality of bit lines BL, other bit lines BL except for the plurality of bit lines BL respectively connected to the bit line pads BLP, that is, the plurality of bit lines BL not connected to the bit line pads BLP in the first edge portion of the cell array area CELL, each include a bit line extension portion BLE. In the first edge portion of the cell array area CELL, the bit line extension portion BLE is located between two adjacent bit line pads BLP from among the plurality of bit line pads BLP to face each of the two adjacent bit line pads BLP in the first horizontal direction (the X direction). Herein, in the first edge portion of the cell array area CELL, the bit line BL connected to the bit line pad BLP may be referred to as a first bit line, and another bit line BL not connected to the bit line pad BLP may be referred to as a second bit line.

As shown in FIG. 4, each of the plurality of bit line pads BLP may include a pad connection portion PE and a main pad portion PM, the pad connection portion PE having a gradually increasing width in the first horizontal direction (the X direction) with an increasing distance, in the second horizontal direction (the Y direction), from the bit line BL connected to each of the plurality of bit line pads BLP, and the main pad portion PM being spaced apart from the connected bit line BL in the second horizontal direction (the Y direction) with the pad connection portion PE therebetween. In the first horizontal direction (the X direction), the width of the main pad portion PM is greater than the width of the bit line BL. In some embodiments, the width of the main pad portion PM in the first horizontal direction (the X direction) may be constant in the second horizontal direction (the Y direction).

Each of the plurality of bit line pads BLP may be located apart from, in the first horizontal direction (the X direction), the bit line extension portion BLE of the bit line BL that is adjacent to each of the plurality of bit line pads BLP such that each of the plurality of bit line pads BLP is not arranged on an extension line, in the second horizontal direction (the Y direction), of the bit line extension portion BLE of the bit line BL adjacent to each of the plurality of bit line pads BLP. The planar shape of each of the plurality of bit line pads BLP may be symmetric about an extension line, in the second horizontal direction (the Y direction), of the bit line BL (the first bit line) corresponding to each of the plurality of bit line pads BLP.

As shown in FIG. 5C, like the plurality of bit lines BL, the plurality of bit line pads BLP may each include a lower conductive layer 130, an intermediate conductive layer 132, and an upper conductive layer 134, which are sequentially stacked in the stated order over the substrate 102. Each of the plurality of bit line pads BLP may be covered by a pad insulating capping structure. The pad insulating capping structure may include the insulating capping layer 142, an insulating thin film 146, and an upper insulating capping layer 148. Each of the insulating capping layer 142, the insulating thin film 146, and the upper insulating capping layer 148, which constitute the pad insulating capping structure, may include a silicon nitride film. The sidewalls of both the pad insulating capping structure and the plurality of bit line pads BLP may be respectively covered by a plurality of insulating spacers 152.

As shown in FIGS. 4, 5A, 5D, and 5E, a plurality of conductive landing pads LP and a plurality of conductive dummy landing pads DLP may be arranged at a first vertical level LV1 over the plurality of bit lines BL in the cell array area CELL. Herein, the plurality of conductive dummy landing pads DLP may be referred to as a conductive dummy structure.

The plurality of conductive landing pads LP and the plurality of conductive dummy landing pads DLP may include the same material. In some embodiments, the plurality of conductive landing pads LP and the plurality of conductive dummy landing pads DLP may each include a metal, a conductive metal nitride, or a combination thereof. For example, the plurality of conductive landing pads LP and the plurality of conductive dummy landing pads DLP may each include, but are not limited to, tungsten (W). As shown in FIG. 5A, a buried contact BC may be connected to a conductive landing pad LP via a conductive contact plug 162. The conductive contact plug 162 may include, but is not limited to, TiN.

As shown in FIG. 4, the cell array area CELL may include a landing pad area LPA, in which the plurality of conductive landing pads LP are arranged, and a dummy landing pad area DLPA, in which the plurality of conductive dummy landing pads DLP are arranged. The plurality of conductive landing pads LP and the plurality of conductive dummy landing pads DLP may be arranged to overlap the plurality of bit lines BL in a vertical direction (a Z direction). The plurality of conductive dummy landing pads DLP may be located closer to the second interface area IF2 in the second horizontal direction (the Y direction) than the plurality of conductive landing pads LP. The plurality of conductive dummy landing pads DLP may be located closer to the first and second edge portions, in which the plurality of bit line pads BLP and a plurality of bit line extension portions BLE are arranged, of the cell array area CELL than the plurality of conductive landing pads LP. The dummy landing pad area DLPA may be located closer to the plurality of bit line pads BLP than the landing pad area LPA.

The plurality of conductive dummy landing pads DLP may be arranged not to overlap the bit line extension portion BLE of each of the plurality of bit lines BL (second bit lines) in the vertical direction (the Z direction). Due to such an arrangement described above, a separation distance D1 (see FIG. 4) in the second horizontal direction (the Y direction) between an end of the bit line extension portion BLE of each of the plurality of bit lines BL (second bit lines) and portions, which cover the bit line BL, of the plurality of conductive dummy landing pads DLP may be sufficiently secured. Therefore, in a fabrication process of the integrated circuit device 100, even when subsequent processes are performed while the end of the bit line extension portion BLE is exposed because a portion, which covers the end of the bit line extension portion BLE, of the insulating spacer 152 is locally damaged, a conductive structure, such as the dummy landing pad DLP, is not arranged on the bit line extension portion BLE, and thus, a leakage path between the bit line BL and the dummy landing pad DLP via the end of the bit line extension portion BLE may be cut off. Therefore, unintended short-circuits between the dummy landing pad DLP and the plurality of bit lines BL may be prevented, thereby improving the reliability of the integrated circuit device 100.

As shown in FIG. 5C, a pad contact plug BPC may be arranged on each of the plurality of bit line pads BLP to pass through, in the vertical direction (the Z direction), the insulating capping layer 142, the insulating thin film 146, and the upper insulating capping layer 148 that constitute the pad insulating capping structure. The pad contact plug BPC may be in contact with the upper surface of the bit line pad BLP. The pad contact plug BPC may include a metal or a conductive metal nitride. For example, the pad contact plug BPC may include, but is not limited to, tungsten (W).

A pad wiring layer 164P may be arranged on the pad contact plug BPC. The pad wiring layer 164P may be connected to the bit line pad BLP via the pad contact plug BPC. A plurality of pad wiring layers 164P respectively connected to the plurality of bit line pads BLP may be arranged at the first vertical level LV1, similar to the plurality of conductive landing pads LP and the plurality of conductive dummy landing pads DLP. Each of the plurality of pad wiring layers 164P may include the same material as a constituent material of each of the plurality of conductive landing pads LP and the plurality of conductive dummy landing pads DLP. For example, each of the plurality of pad wiring layers 164P may include, but is not limited to, tungsten (W).

As shown in FIGS. 4 and 5C, the integrated circuit device 100 may include a plurality of dummy buried contacts DBC. The plurality of dummy buried contacts DBC may be arranged over the substrate 102 so as to be at the same level as the plurality of buried contacts BC. A dummy buried contact area DBCA, in which the plurality of dummy buried contacts DBC are arranged over the substrate 102, may be closer to the second interface area IF2 than a buried contact area BCA in which a buried contact BC is arranged. A constituent material of each of the plurality of dummy buried contacts DBC may be the same as a constituent material of each of the plurality of buried contacts BC.

As shown in FIG. 4, in the first edge portion of the cell array area CELL, the plurality of dummy buried contacts DBC may include a first group of dummy buried contacts DBC, which are arranged on an extension line of the bit line BL (the second bit line) including the bit line extension portion BLE, and a second group of dummy buried contacts DBC arranged between the bit line extension portion BLE and the bit line pad BLP. The first group of dummy buried contacts DBC may be arranged in a line in the second horizontal direction (the Y direction) between two adjacent bit line pads BLP from among the plurality of bit line pads BLP.

From the viewpoint of a plane (the X-Y plane), the shape and the size of each of the first group of dummy buried contacts DBC may be different from the shape and the size of each of the second group of dummy buried contacts DBC. Among the plurality of dummy buried contacts DBC, the second group of dummy buried contacts DBC may face the bit line extension portion BLE in the first horizontal direction (the X direction).

In some embodiments, in the second horizontal direction (the Y direction), a separation distance between two buried contacts BC selected from the plurality of buried contacts BC may be equal to a separation distance between two dummy buried contacts DBC selected from the plurality of dummy buried contacts DBC. In addition, in the second horizontal direction (the Y direction), the width of each of the plurality of buried contacts BC may be equal to the width of each of the plurality of dummy buried contacts DBC. Therefore, the plurality of buried contacts BC and the plurality of dummy buried contacts DBC may be arranged at equal pitches in the second horizontal direction (the Y direction).

As shown in FIGS. 5C and 5E, in the first edge portion of the cell array area CELL, each of the plurality of dummy buried contacts DBC may be covered by a conductive dummy contact plug 162D. A constituent material of the conductive dummy contact plug 162D may be the same as a constituent material of the conductive contact plug 162 that covers the buried contact BC. For example, the conductive dummy contact plug 162D may include, but is not limited to, TiN.

As shown in FIGS. 5A to 5E, an insulating film 170 may fill a space between each of the plurality of conductive landing pads LP, the plurality of conductive dummy landing pads DLP, and the plurality of pad wiring layers 164P. The insulating film 170 may include a silicon nitride film, a silicon oxide film, or a combination thereof.

As shown in FIGS. 5D and 5E, a plurality of peripheral transistors PTR may be arranged on the substrate 102 in the core area CORE. Each of the plurality of peripheral transistors PTR may include a gate dielectric film 128 arranged on the substrate 102 and a peripheral gate PG arranged on the gate dielectric film 128. The gate dielectric film 128 may include a silicon oxide film, a high-k dielectric film, or a combination thereof. The high-k dielectric film may include, but is not limited to, HfO₂, Al₂O₃, HfAlO₃, Ta₂O₃, or TiO₂. Similar to the plurality of bit lines BL arranged in the cell array area CELL, the peripheral gate PG may include a lower conductive layer 130, an intermediate conductive layer 132, and an upper conductive layer 134, which are sequentially stacked in the stated order on the gate dielectric film 128. Each of the plurality of peripheral transistors PTR may further include a pair of source/drain regions formed in the substrate 102 on both sides of the peripheral gate PG. The upper surface of the peripheral gate PG may be covered by an insulating capping layer 142. The sidewall of the peripheral gate PG may be covered by an insulating spacer 144. Each of the insulating capping layer 142 and the insulating spacer 144 may include, but is not limited to, a silicon nitride film.

As shown in FIGS. 5D and 5E, an insulating thin film 146 and a gap-fill insulating film 145 may be sequentially stacked in the stated order on the device isolation film 112 in the second interface area IF2. The gap-fill insulating film 145 may include a silicon oxide film. The gap-fill insulating film 145 may be covered by the upper insulating capping layer 148, and the upper insulating capping layer 148 may be covered by the insulating film 170.

The integrated circuit device 100 described with reference to FIGS. 1 to 5E includes the plurality of bit lines (second bit lines) not connected to the bit line pads BLP in the first edge portion of the cell array area CELL, and each of the plurality of second bit lines includes the bit line extension portion BLE located to face, in the first horizontal direction (the X direction), the bit line pad BLP connected to the bit line BL (the first bit line) that is adjacent to each of the plurality of second bit lines. The plurality of conductive dummy landing pads DLP arranged over the plurality of bit lines BL are located farther from the second interface area IF2 than the bit line extension portion BLE of each of the plurality of second bit lines not to overlap the bit line extension portion BLE of each of the plurality of second bit lines in the vertical direction (the Z direction). Due to such an arrangement described above, the separation distance D1 in the second horizontal direction (the Y direction) between the end of the bit line extension portion BLE of each of the plurality of bit lines BL (second bit lines) and portions, which cover the bit line BL, of the plurality of conductive dummy landing pads DLP may be sufficiently secured. Therefore, in the fabrication process of the integrated circuit device 100, even when subsequent processes are performed while the end of the bit line extension portion BLE is exposed because the portion, which covers the end of the bit line extension portion BLE, of the insulating spacer 152 is locally damaged, a conductive structure, such as the dummy landing pad DLP, is not arranged on the bit line extension portion BLE, and thus, a leakage path between the bit line BL and the dummy landing pad DLP via the end of the bit line extension portion BLE may be cut off. Therefore, unintended short-circuits between the dummy landing pad DLP and the plurality of bit lines BL may be prevented, thereby improving the reliability of the integrated circuit device 100.

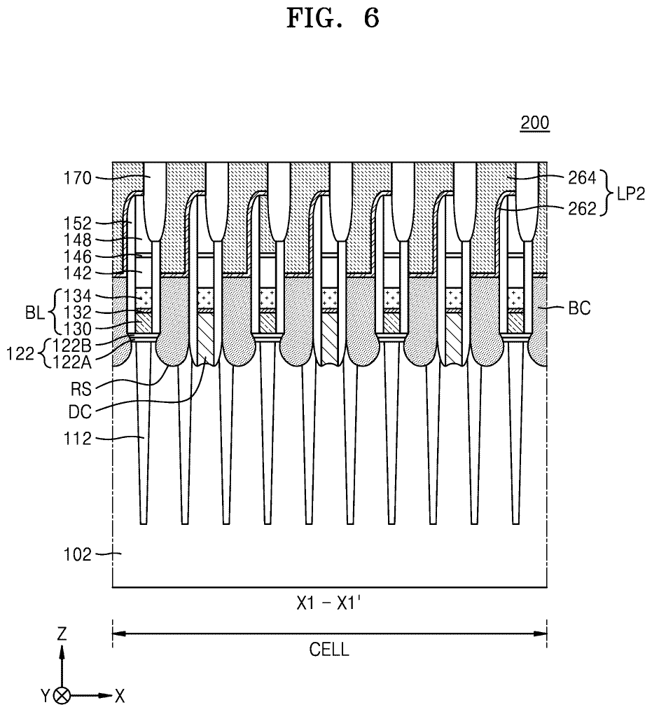

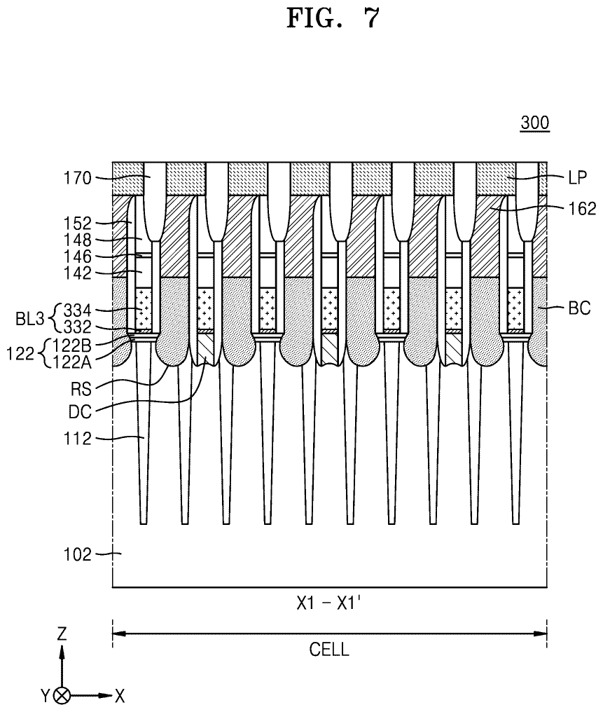

FIGS. 6 and 7 are cross-sectional views respectively illustrating integrated circuit devices 200 and 300 according to some embodiments. FIGS. 6 and 7 respectively illustrate cross-sectional configurations of portions of the integrated circuit devices 200 and 300, the portions corresponding to a cross-section taken along the line X1-X1′ of FIG. 3. In FIGS. 6 and 7, the same reference numerals as in FIGS. 1 to 5E respectively denote the same members, and here, repeated descriptions thereof are omitted.

Referring to FIG. 6, the integrated circuit device 200 has substantially the same configuration as the integrated circuit device 100 described with reference to FIGS. 1 to 5E. However, the integrated circuit device 200 includes a plurality of conductive landing pads LP2 arranged in the cell array area CELL. Each of the plurality of conductive landing pads LP2 may be arranged to partially overlap the buried contact BC in the vertical direction (the Z direction). Each of the plurality of conductive landing pads LP2 may include a conductive barrier film 262 and a main conductive layer 264. The conductive barrier film 262 may include Ti, TiN, or a combination thereof. The main conductive layer 264 may include a metal, a metal nitride, conductive polysilicon, or a combination thereof. For example, the main conductive layer 264 may include W. The plurality of conductive landing pads LP2 may respectively have a plurality of island pattern shapes in a plan view. The plurality of conductive landing pads LP2 may be electrically insulated from each other by the insulating film 170.

Referring to FIG. 7, the integrated circuit device 300 has substantially the same configuration as the integrated circuit device 100 described with reference to FIGS. 1 to 5E. However, the integrated circuit device 300 includes a plurality of bit lines BL3 arranged in the cell array area CELL. The plurality of bit lines BL3 have substantially the same configuration as the plurality of bit lines BL described with reference to FIGS. 5A, 5B, 5D, and 5E. However, each of the plurality of bit lines BL3 includes a first conductive pattern 332 and a second conductive pattern 334, which are sequentially stacked in the stated order over the substrate 102. Each of the first conductive pattern 332 and the second conductive pattern 334 may include TiN, TiSiN, W, tungsten silicide, or a combination thereof. In some embodiments, the first conductive pattern 332 may include TiN, TiSiN, or a combination thereof and the second conductive pattern 334 may include W, but the inventive concept is not limited thereto.

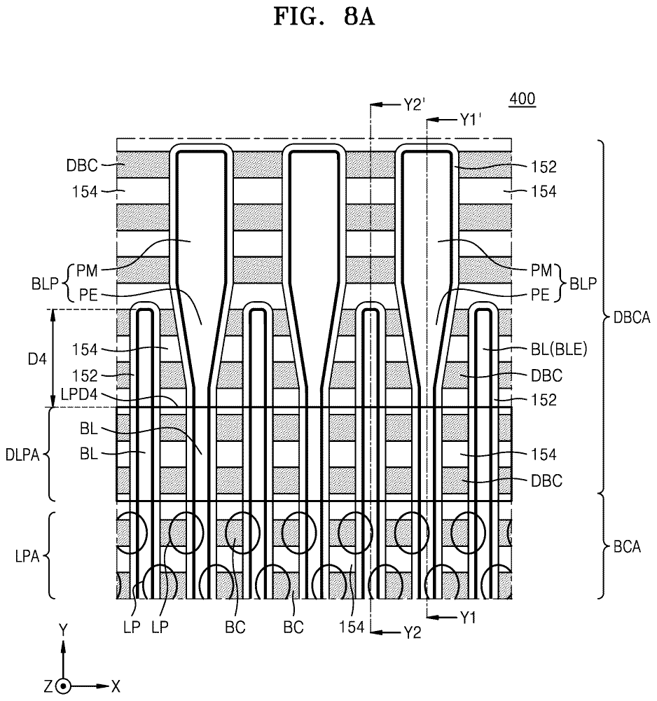

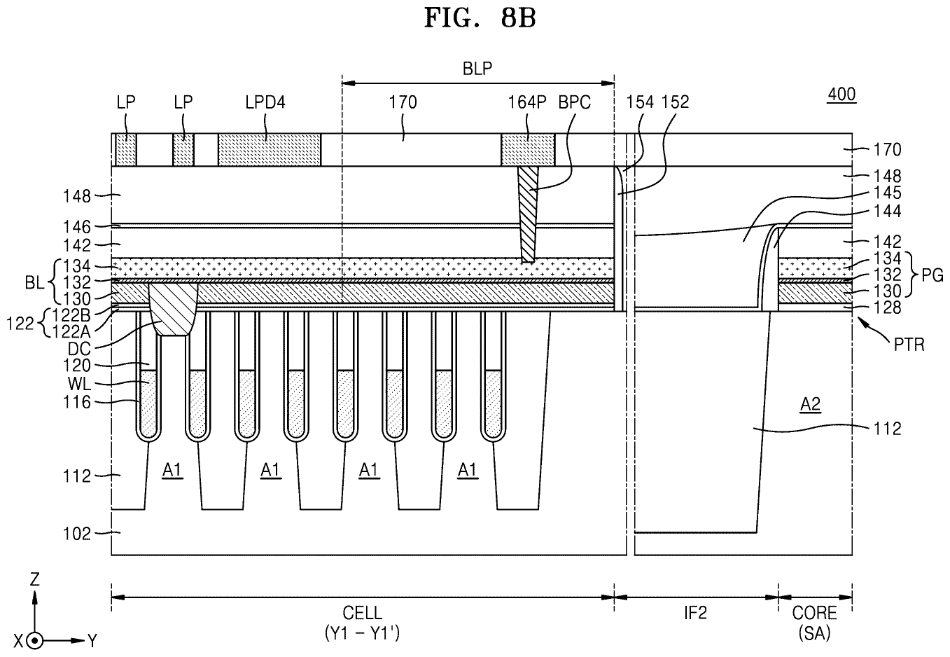

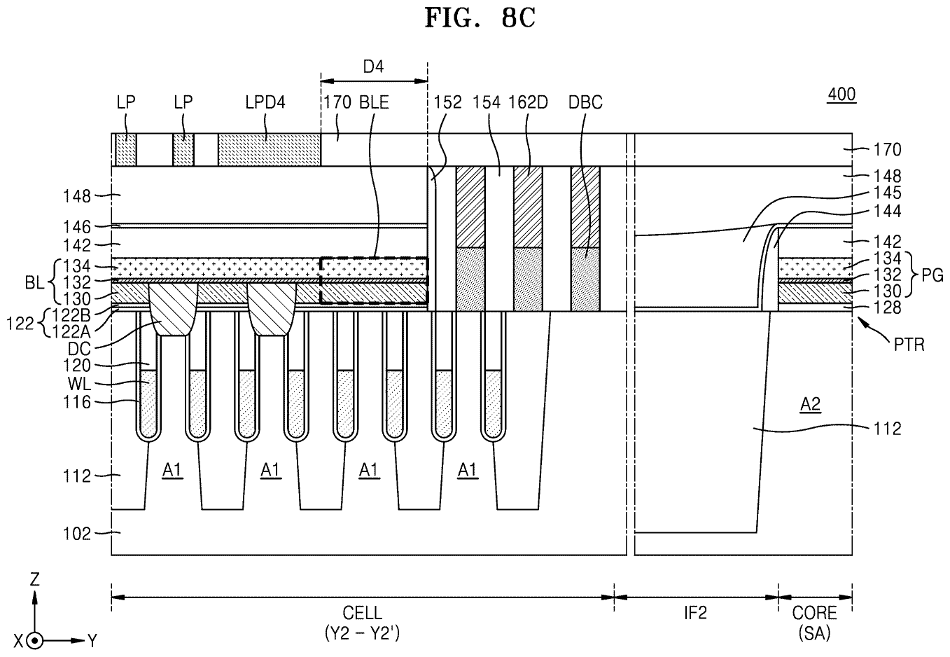

FIGS. 8A, 8B, and 8C are diagrams illustrating an integrated circuit device 400 according to some embodiments. More specifically, FIG. 8A is a plan view of some components in a portion of the cell array area CELL of the integrated circuit device 400. FIG. 8A illustrates an enlarged view of some components in a portion of the integrated circuit device 400, the portion corresponding to the region EX2 of FIG. 2. FIG. 8B is a cross-sectional view of the integrated circuit device 400, taken along a line Y1-Y1′ of FIG. 8A and an extension line thereof, and FIG. 8C is a cross-sectional view of the integrated circuit device 400, taken along a line Y2-Y2′ of FIG. 8A and an extension line thereof. In FIGS. 8A, 8B, and 8C, the same reference numerals as in FIGS. 1 to 5E respectively denote the same members, and here, repeated descriptions thereof are omitted.

Referring to FIGS. 8A, 8B, and 8C, the integrated circuit device 400 has substantially the same configuration as the integrated circuit device 100 described with reference to FIGS. 1 to 5E. However, the integrated circuit device 400 includes a conductive dummy landing plate dam LPD4 arranged to overlap the plurality of bit lines BL in the vertical direction (the Z direction) in the dummy landing pad area DLPA of the cell array area CELL. A constituent material of the conductive dummy landing plate dam LPD4 may be the same as a constituent material of each of the plurality of conductive landing pads LP. Herein, the conductive dummy landing plate dam LPD4 may be referred to as a conductive dummy structure.

In the second horizontal direction (the Y direction), the conductive dummy landing plate dam LPD4 may be arranged closer to the plurality of bit line pads BLP than the plurality of conductive landing pads LP. That is, the conductive dummy landing plate dam LPD4 may be arranged closer to the first and second edge portions of the cell array area CELL, in which the plurality of bit line pads BLP and the plurality of bit line extension portions BLE are arranged, than the plurality of conductive landing pads LP.

The conductive dummy landing plate dam LPD4 may be arranged not to overlap the bit line extension portion BLE of each of the plurality of bit lines BL (second bit lines) in the vertical direction (the Z direction). Due to such an arrangement described above, a separation distance D4 in the second horizontal direction (the Y direction) between the end of the bit line extension portion BLE of each of the plurality of bit lines BL (second bit lines) and a portion, which covers the bit line BL, of the conductive dummy landing plate dam LPD4 may be sufficiently secured. Therefore, in a fabrication process of the integrated circuit device 400, even when subsequent processes are performed while the end of the bit line extension portion BLE is exposed because the portion, which covers the end of the bit line extension portion BLE, of the insulating spacer 152 is locally damaged, a conductive structure, such as the conductive dummy landing plate dam LPD4, is not arranged on the bit line extension portion BLE, and thus, a leakage path between the bit line BL and the conductive dummy landing plate dam LPD4 via the end of the bit line extension portion BLE may be cut off. Therefore, unintended short-circuits between the conductive dummy landing plate dam LPD4 and the plurality of bit lines BL may be prevented, thereby improving the reliability of the integrated circuit device 400.

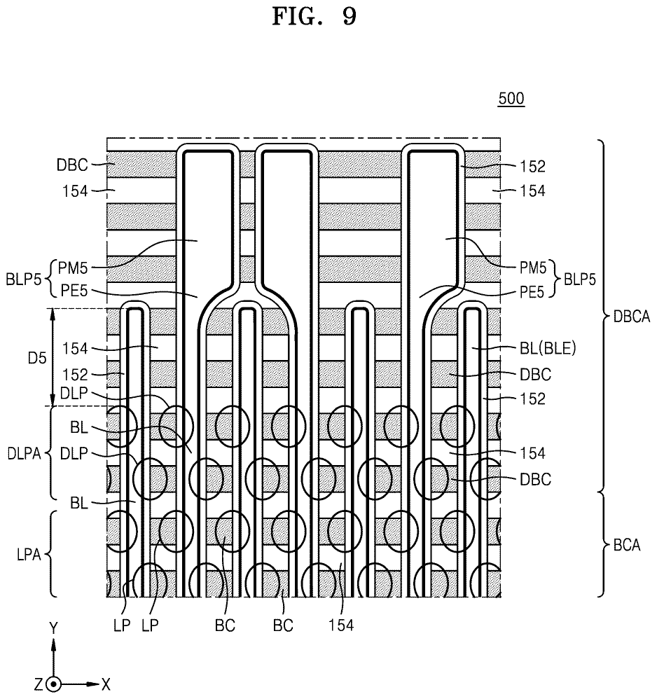

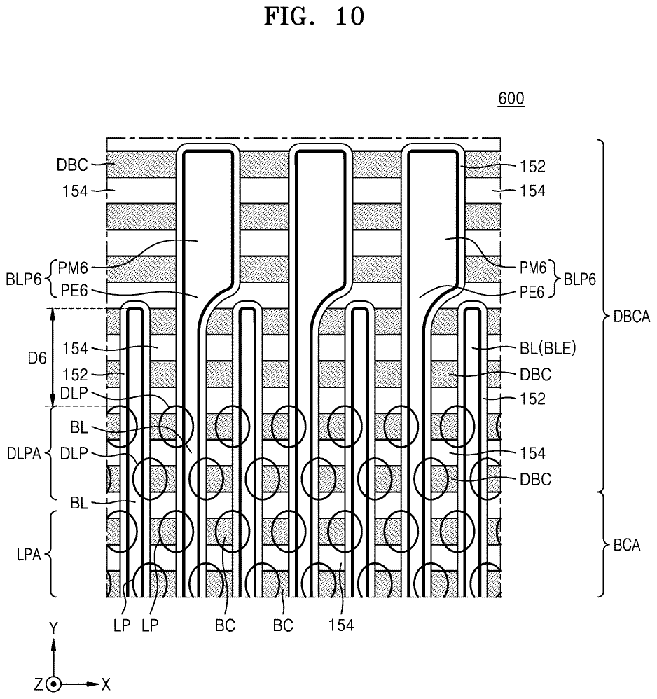

FIGS. 9 and 10 are cross-sectional views respectively illustrating integrated circuit devices 500 and 600 according to some embodiments. FIGS. 9 and 10 respectively illustrate enlarged views of some components in portions of the integrated circuit devices 500 and 600, the portions corresponding to the region EX2 of FIG. 2. In FIGS. 9 and 10, the same reference numerals as in FIGS. 1 to 5E respectively denote the same members, and here, repeated descriptions thereof are omitted.

Referring to FIG. 9, the integrated circuit device 500 has substantially the same configuration as the integrated circuit device 100 described with reference to FIGS. 1 to 5E. However, the integrated circuit device 500 includes a plurality of bit line pads BLP5 respectively and integrally connected to the plurality of bit lines BL.

The plurality of bit line pads BLP5 have substantially the same configuration as the plurality of bit line pads BLP described with reference to FIGS. 4, 5C, and 5D. However, the planar shape of each of the plurality of bit line pads BLP5 is asymmetric about an extension line, which follows the second horizontal direction (the Y direction), of the bit line BL (which may be referred to as a first bit line) connected to each of the plurality of bit line pads BLP5. In a plan view, a pair of bit line pads BLP5 adjacent to each other in the first horizontal direction (the X direction) from among the plurality of bit line pads BLP5 may respectively have mirror-symmetric shapes to each other about a straight line following the second horizontal direction (the Y direction). The straight line may be an extension line, following the second horizontal direction (the Y direction), of one bit line BL, which is selected from bit lines BL (which may be referred to as second bit lines) not connected to the bit line pads BLP5 in the first edge portion of the cell array area CELL, and which is arranged between the pair of bit line pads BLP5.

Each of the plurality of bit line pads BLP5 may include a pad connection portion PE5 and a main pad portion PM5, the pad connection portion PE5 having a gradually increasing width in the first horizontal direction (the X direction) with an increasing distance, in the second horizontal direction (the Y direction), from the bit line BL connected to each of the plurality of bit line pads BLP5, and the main pad portion PM5 being spaced apart from the connected bit line BL in the second horizontal direction (the Y direction) with the pad connection portion PE5 therebetween. In the first horizontal direction (the X direction), the width of the main pad portion PM5 is greater than the width of the bit line BL. In some embodiments, the width of the main pad portion PM5 may be constant in the second horizontal direction (the Y direction). The bit line extension portion BLE of the bit line BL (the second bit line) not connected to the bit line pad BLP5 in the first edge portion of the cell array area CELL may face the pad connection portion PE5 of the bit line pad BLP5 that is adjacent to the bit line extension portion BLE in the first horizontal direction (the X direction). More detailed configurations of the pad connection portion PE5 and the main pad portion PM5 of the bit line pad BLP5 are substantially the same as those of the pad connection portion PE and the main pad portion PM, which are described with reference to FIG. 4.

Referring to FIG. 10, the integrated circuit device 600 has substantially the same configuration as the integrated circuit device 100 described with reference to FIGS. 1 to 5E. However, the integrated circuit device 600 includes a plurality of bit line pads BLP6 respectively and integrally connected to the plurality of bit lines BL.

The plurality of bit line pads BLP6 have substantially the same configuration as the plurality of bit line pads BLP described with reference to FIGS. 4, 5C, and 5D. However, the planar shape of each of the plurality of bit line pads BLP6 is asymmetric about an extension line, following the second horizontal direction (the Y direction), of the bit line BL (which may be referred to as a first bit line) connected to each of the plurality of bit line pads BLP6. In a plan view, a pair of bit line pads BLP6 adjacent to each other in the first horizontal direction (the X direction) from among the plurality of bit line pads BLP6 may have the same shape.

Each of the plurality of bit line pads BLP6 may include a pad connection portion PE6 and a main pad portion PM6, the pad connection portion PE6 having a gradually increasing width in the first horizontal direction (the X direction) with an increasing distance, in the second horizontal direction (the Y direction), from the bit line BL connected to each of the plurality of bit line pads BLP6, and the main pad portion PM6 being spaced apart from the connected bit line BL in the second horizontal direction (the Y direction) with the pad connection portion PE6 therebetween. In the first horizontal direction (the X direction), the width of the main pad portion PM6 is greater than the width of the bit line BL. In some embodiments, the width of the main pad portion PM6 may be constant in the second horizontal direction (the Y direction). The bit line extension portion BLE of the bit line BL (the second bit line) not connected to the bit line pad BLP6 in the first edge portion of the cell array area CELL may face the pad connection portion PE6 of the bit line pad BLP6 that is adjacent to the bit line extension portion BLE in the first horizontal direction (the X direction). More detailed configurations of the pad connection portion PE6 and the main pad portion PM6 of the bit line pad BLP6 are substantially the same as those of the pad connection portion PE and the main pad portion PM, which are described with reference to FIG. 4.

Similar to the integrated circuit device 100 described with reference to FIGS. 1 to 5E, each of the integrated circuit devices 500 and 600 described with reference to FIGS. 9 and 10 includes the plurality of bit lines BL (second bit lines) not connected to the bit line pads BLP5 or the bit line pads BLP6 in the first edge portion of the cell array area CELL, and each of the plurality of second bit lines includes the bit line extension portion BLE extending toward the second interface area IF2 to face, in the first horizontal direction (the X direction), the bit line pad BLP5 or BLP6 that is connected to the bit line BL (the first bit line) adjacent to each of the plurality of second bit lines. The plurality of conductive dummy landing pads DLP arranged over the plurality of bit lines BL are located farther from the second interface area IF2 than the bit line extension portion BLE of each of the plurality of second bit lines not to overlap the bit line extension portion BLE of each of the plurality of second bit lines in the vertical direction (the Z direction). Due to such an arrangement described above, a separation distance D5 or D6 in the second horizontal direction (the Y direction) between the end of the bit line extension portion BLE of each of the plurality of bit lines BL (second bit lines) and portions, which cover the bit line BL, of the plurality of conductive dummy landing pads DLP may be sufficiently secured. Therefore, in the fabrication process of the integrated circuit device 100, even when subsequent processes are performed while the end of the bit line extension portion BLE is exposed because the portion, which covers the end of the bit line extension portion BLE, of the insulating spacer 152 is locally damaged, a conductive structure, such as the dummy landing pad DLP, is not arranged on the bit line extension portion BLE, and thus, a leakage path between the bit line BL and the dummy landing pad DLP via the end of the bit line extension portion BLE may be cut off. Therefore, unintended short-circuits between the dummy landing pad DLP and the plurality of bit lines BL may be prevented, thereby improving the reliability of the integrated circuit device 100.

Next, methods of fabricating integrated circuit devices according to embodiments are described in detail.

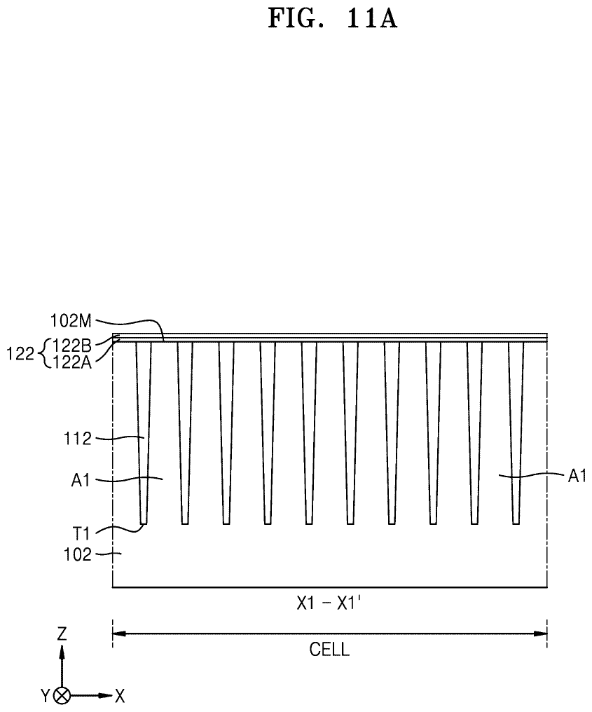

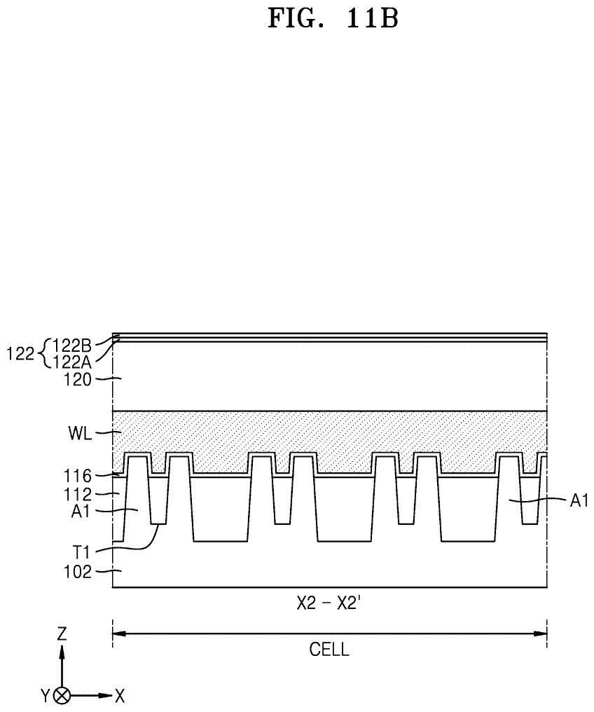

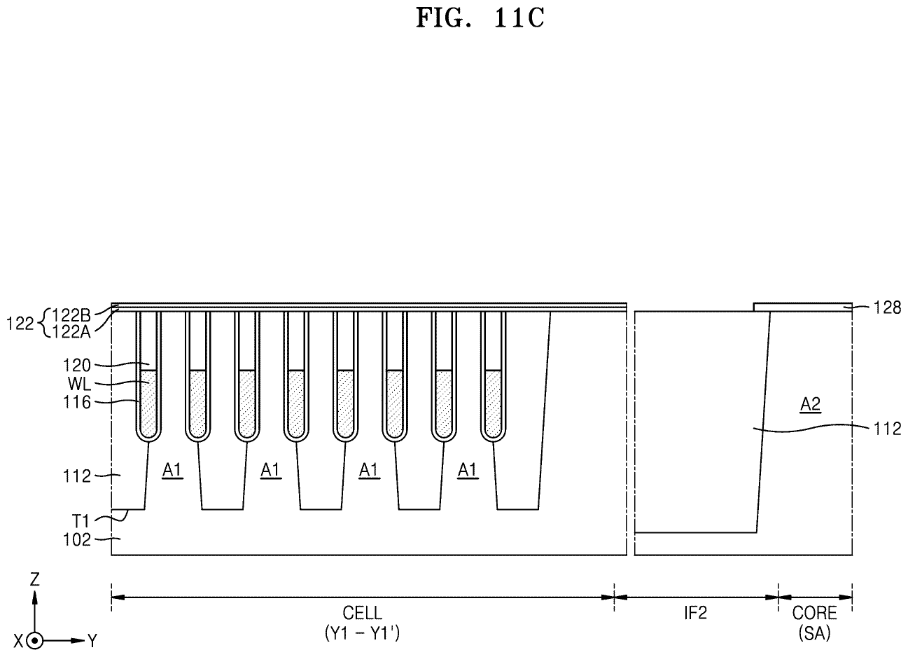

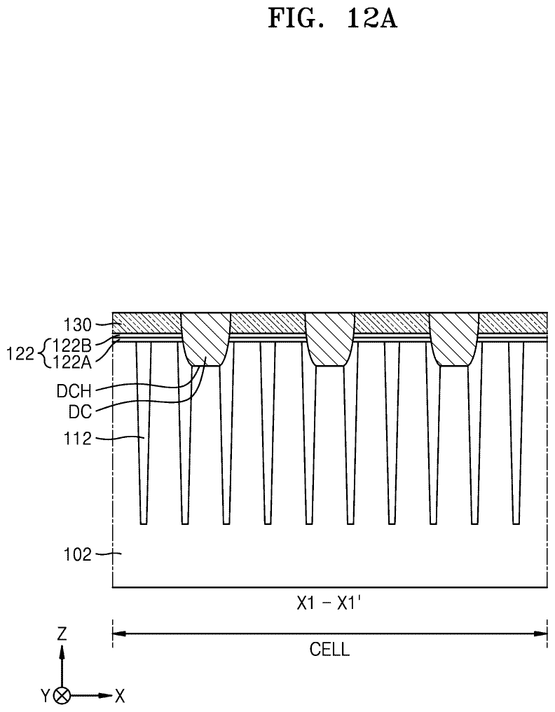

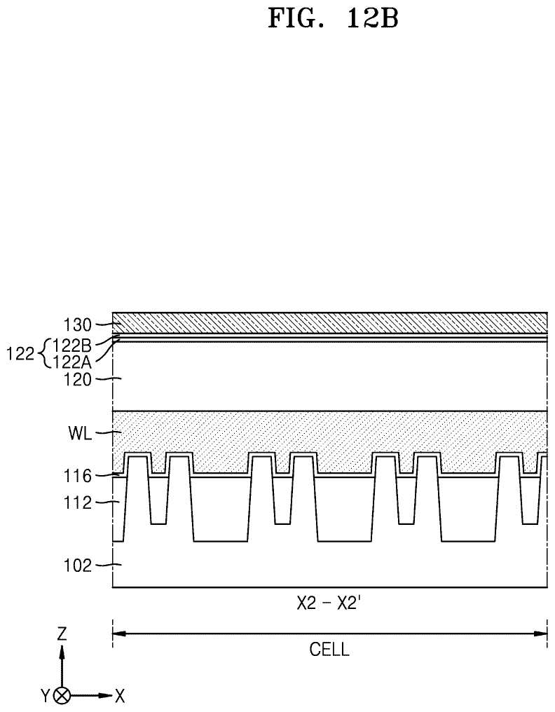

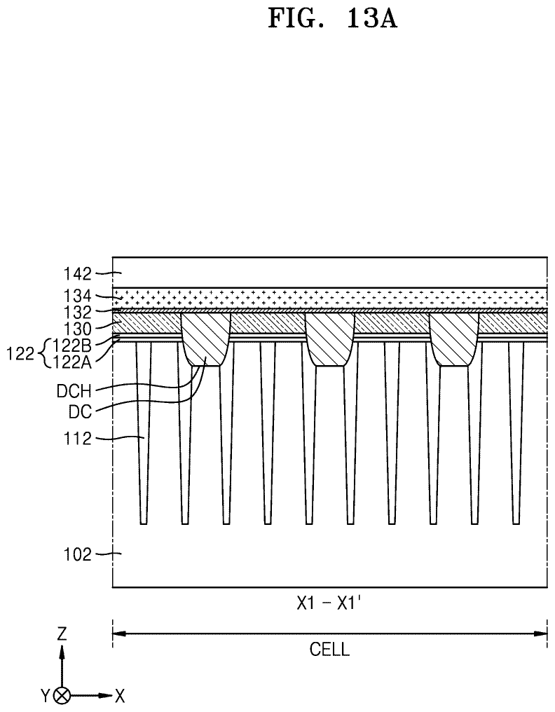

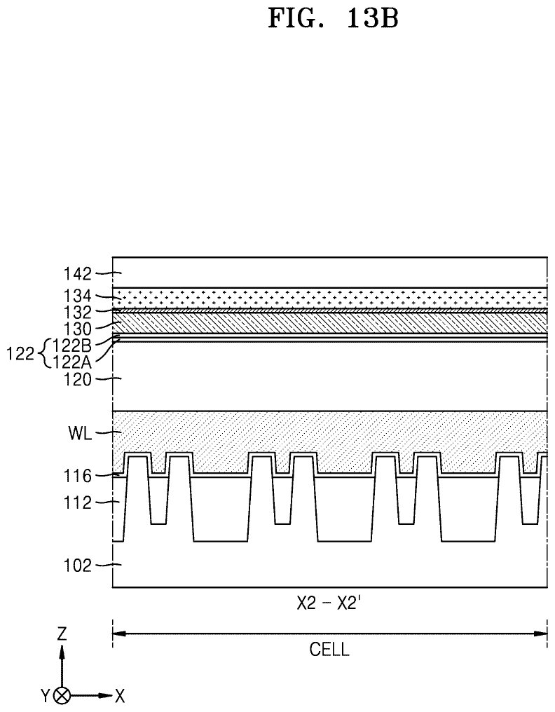

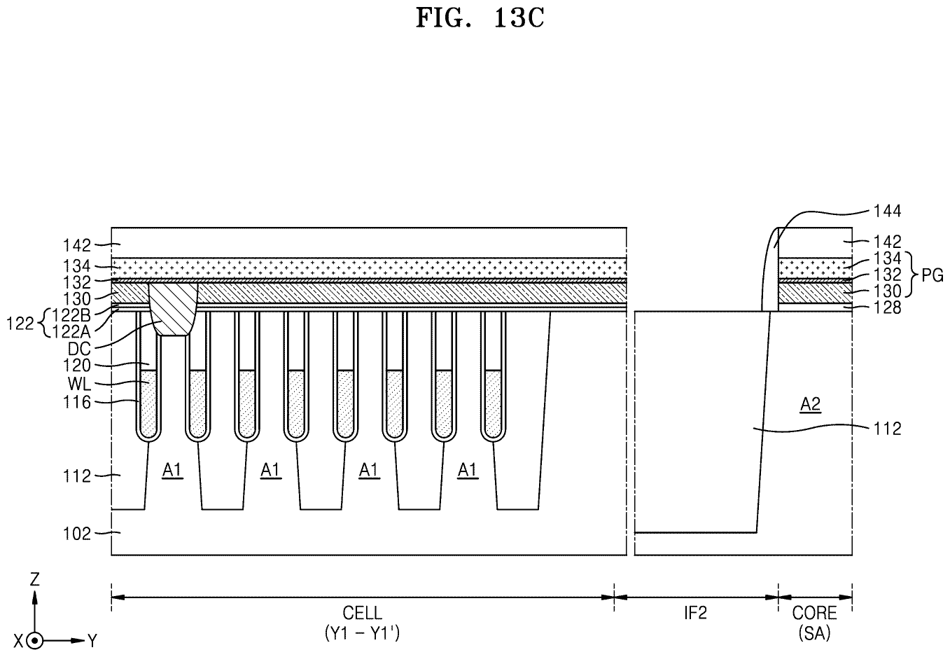

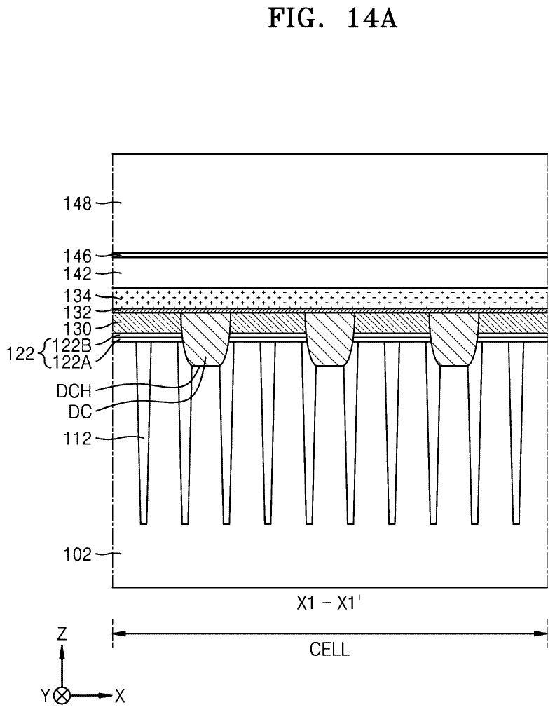

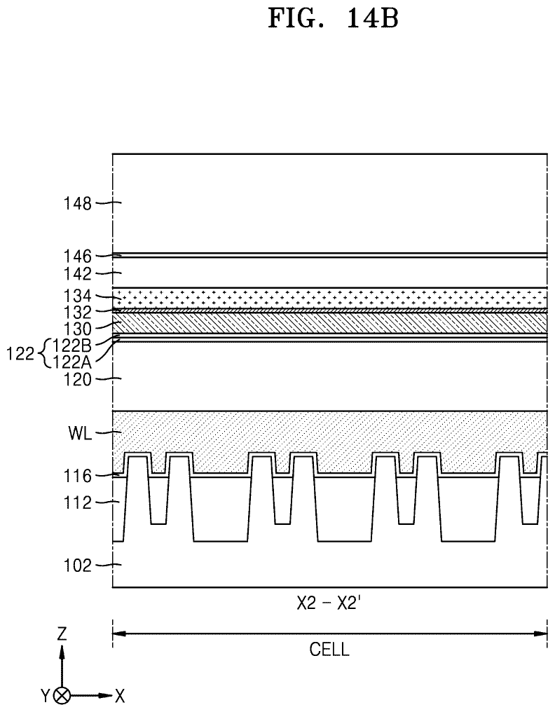

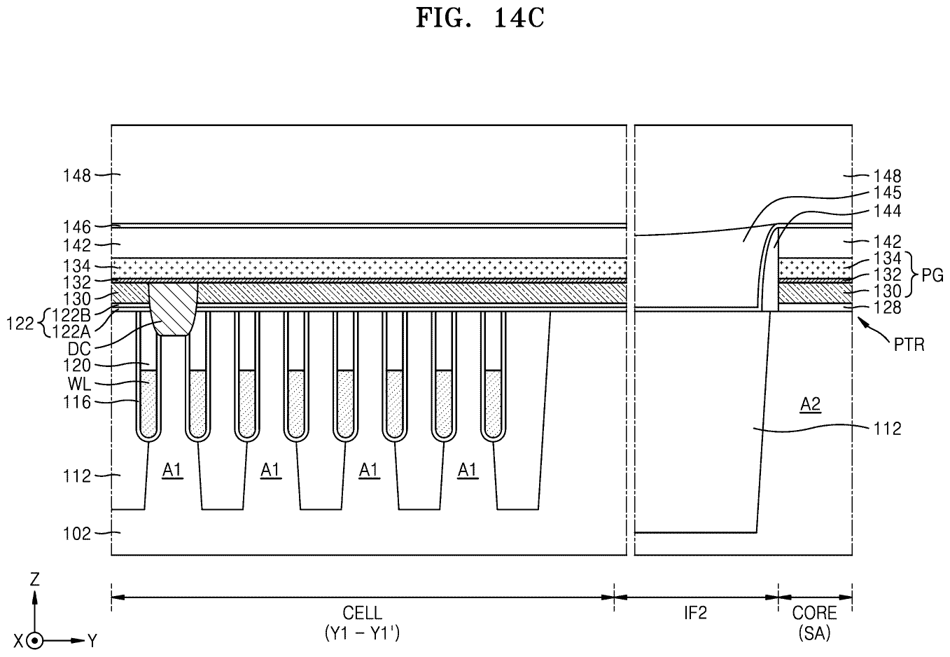

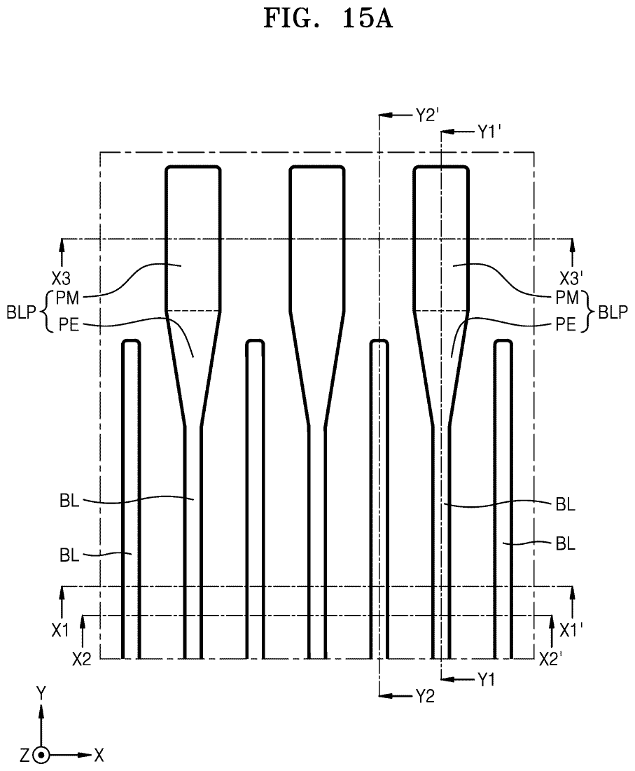

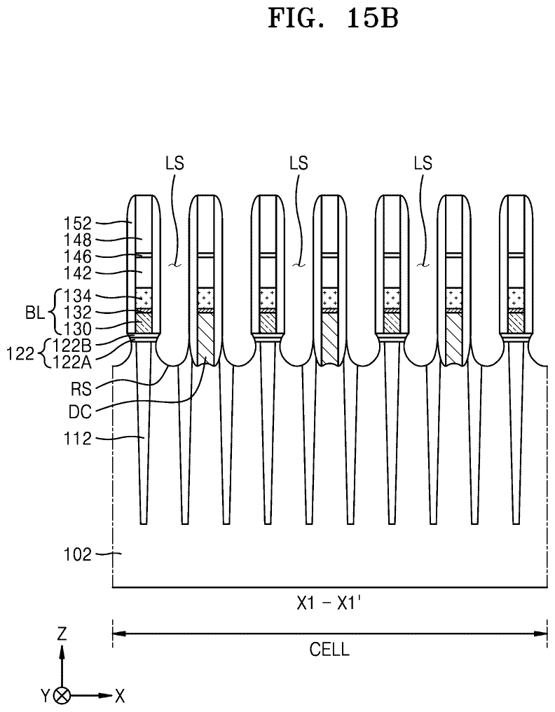

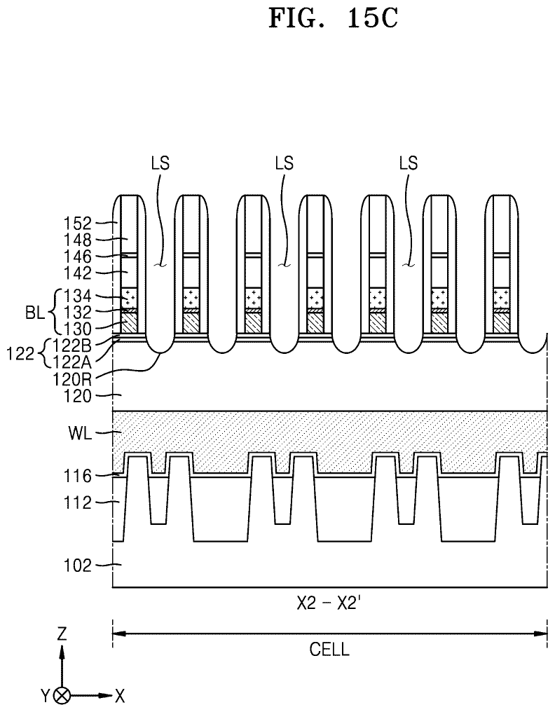

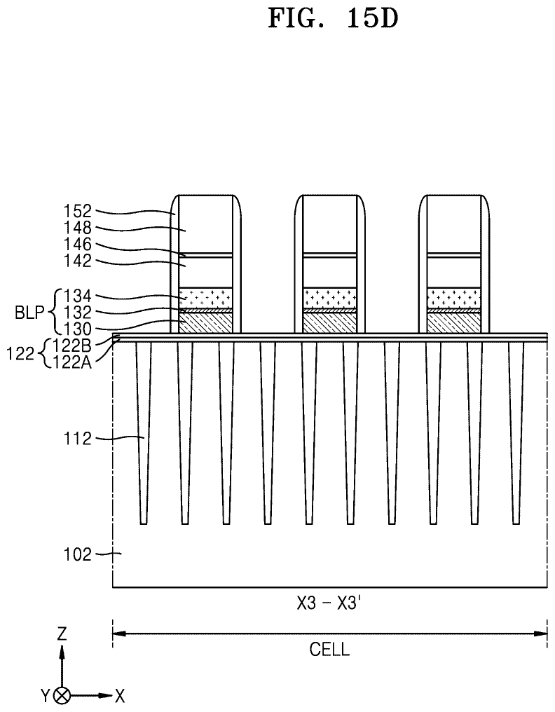

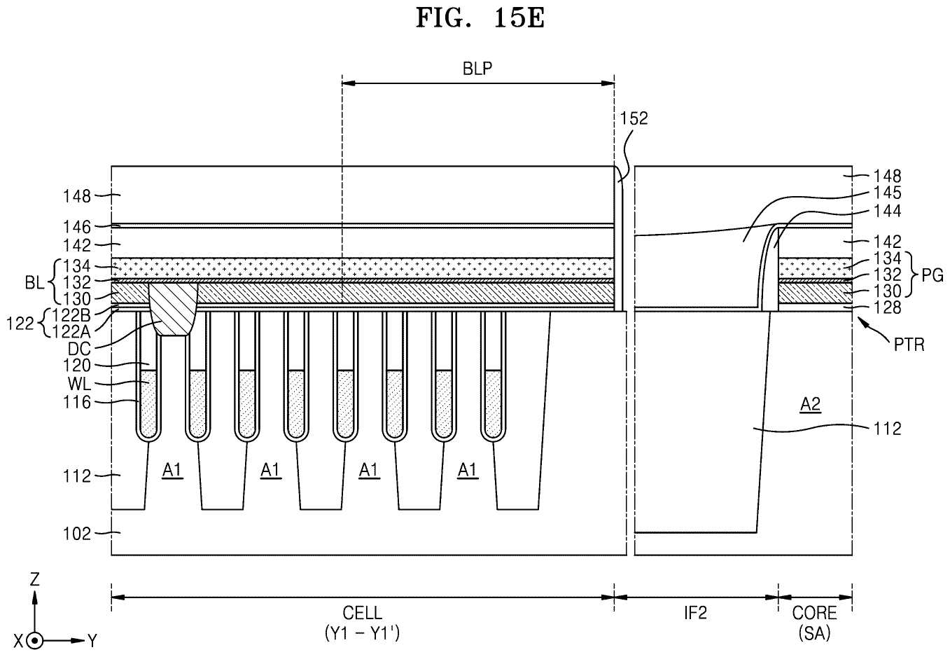

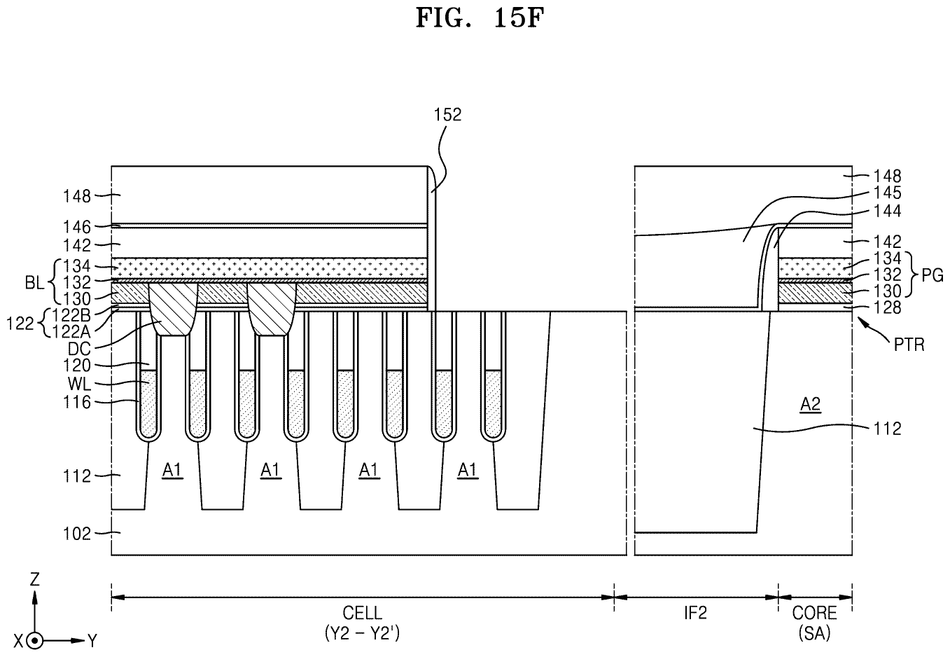

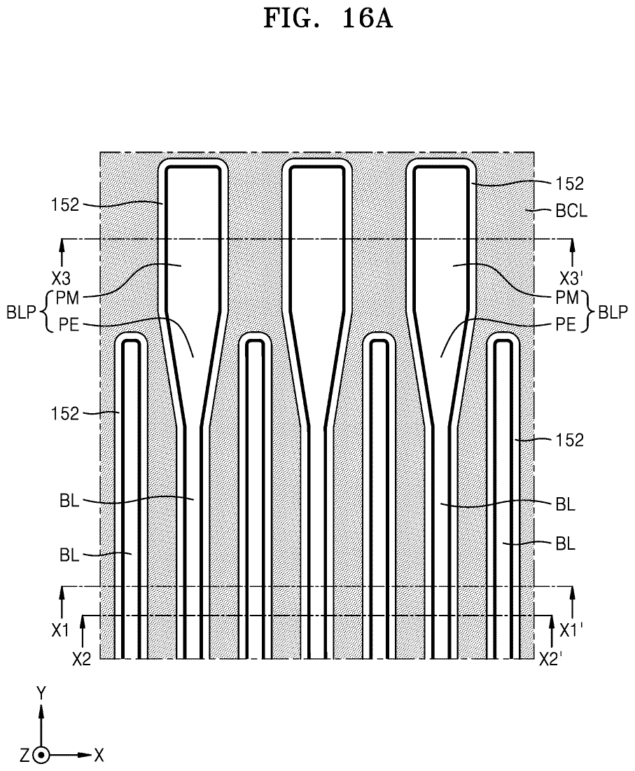

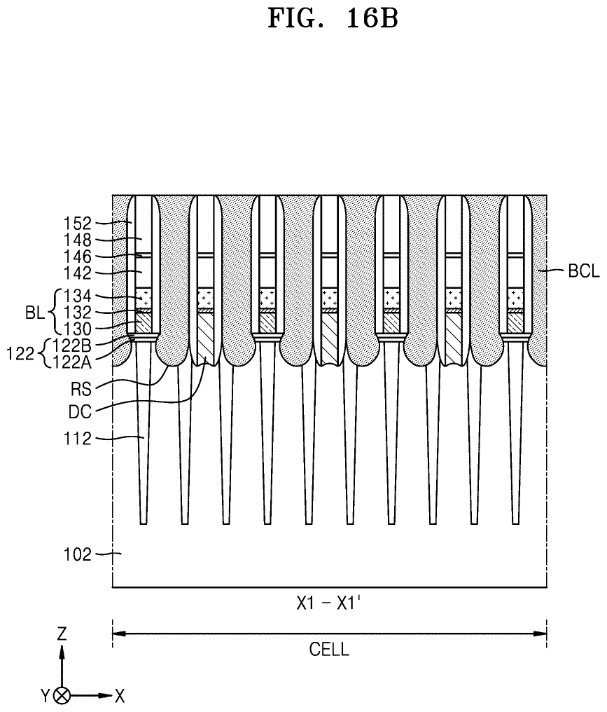

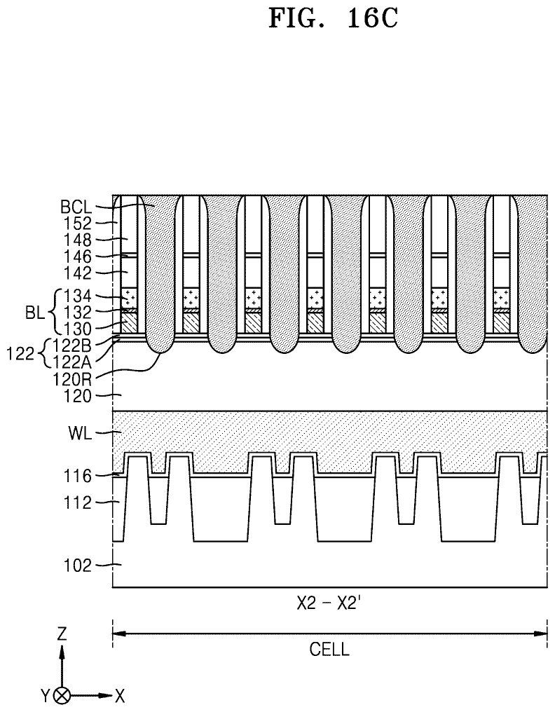

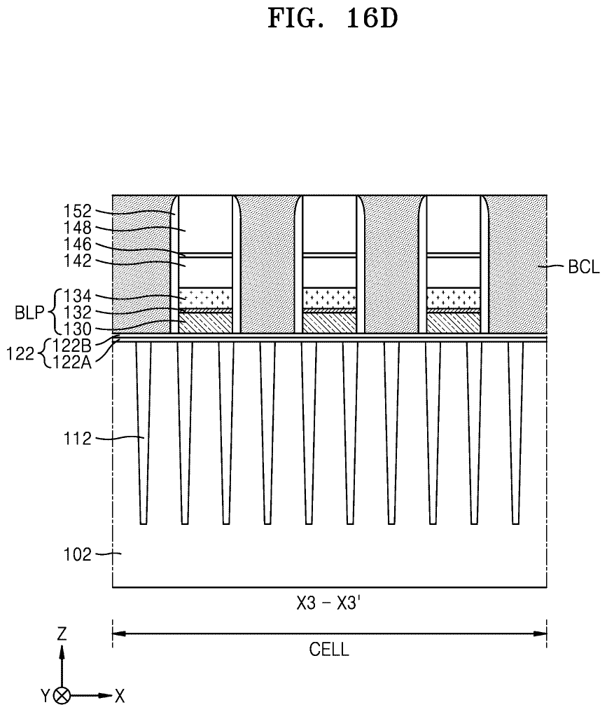

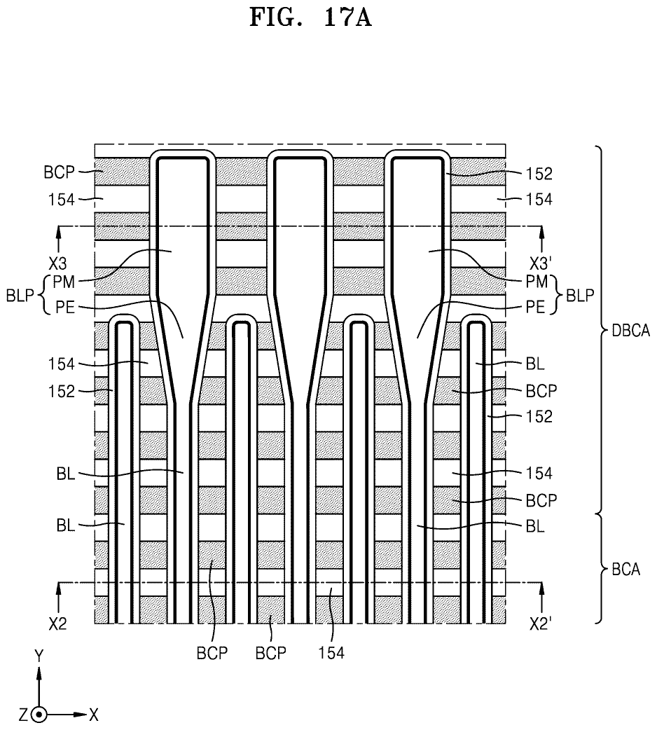

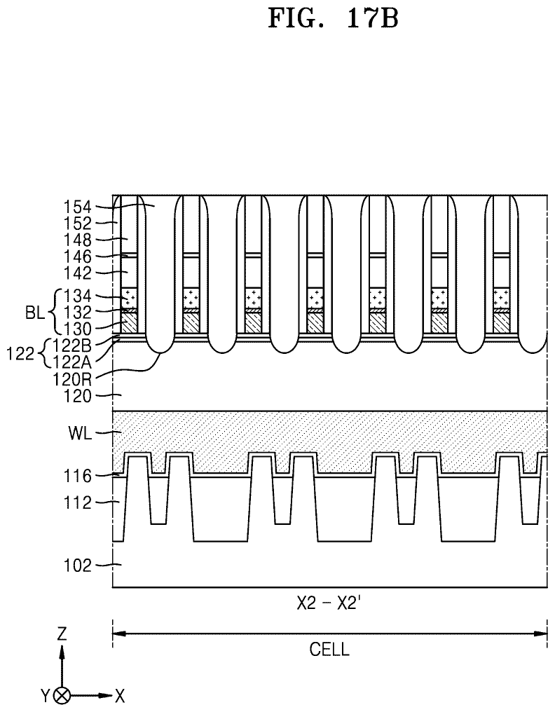

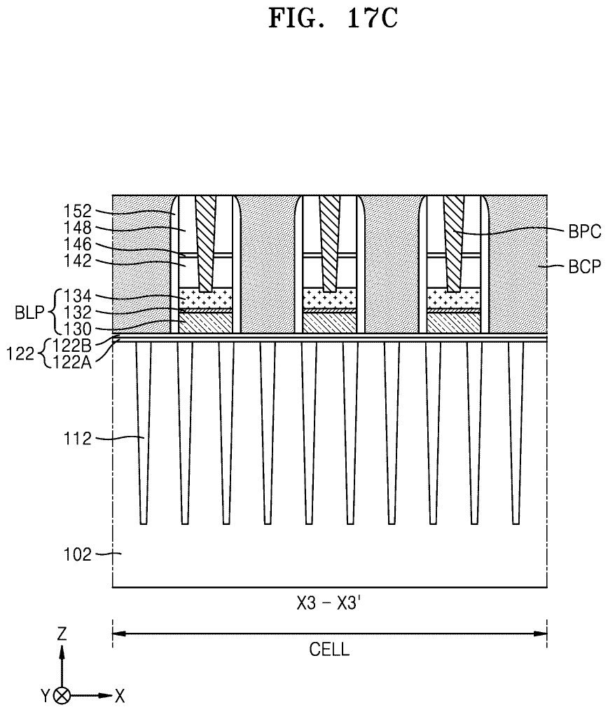

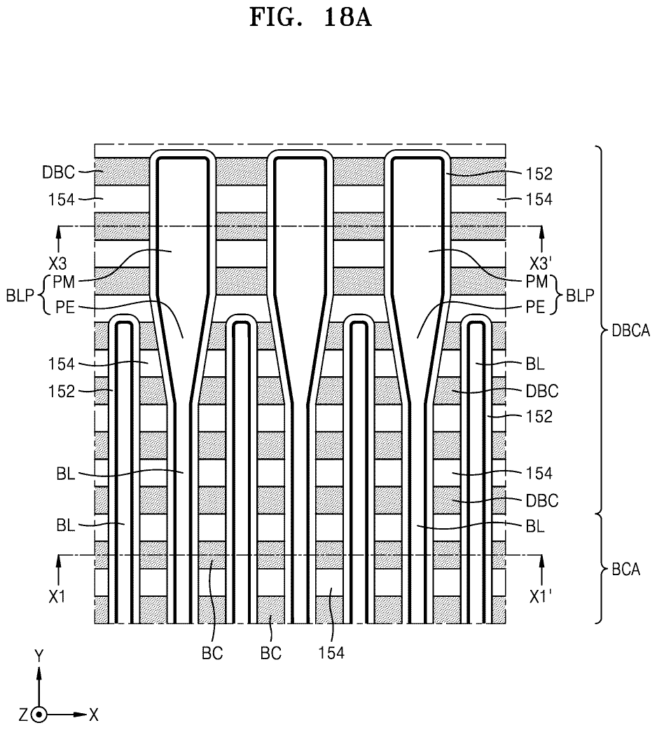

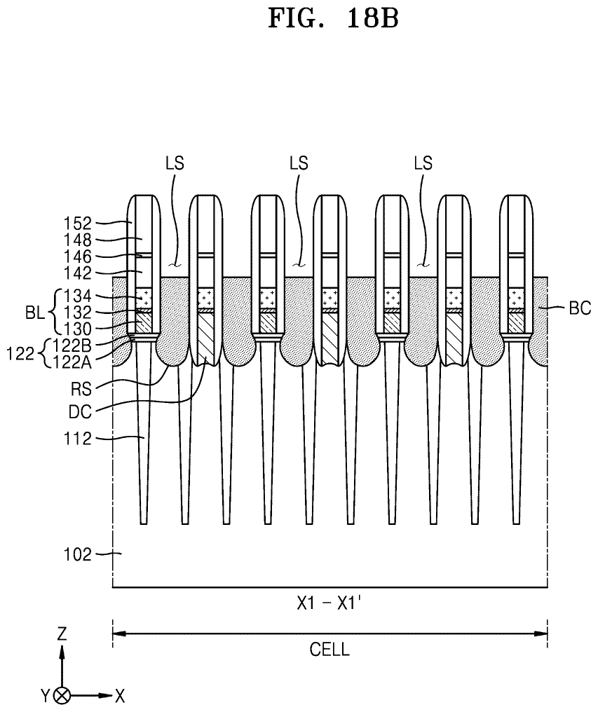

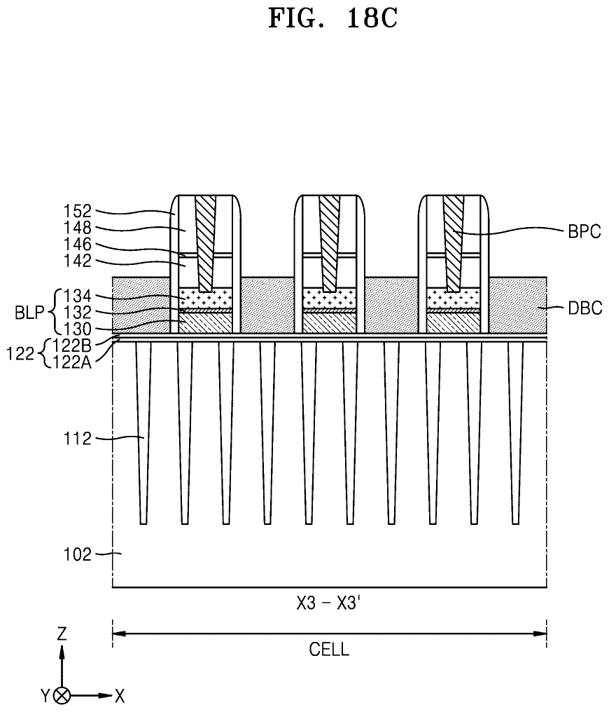

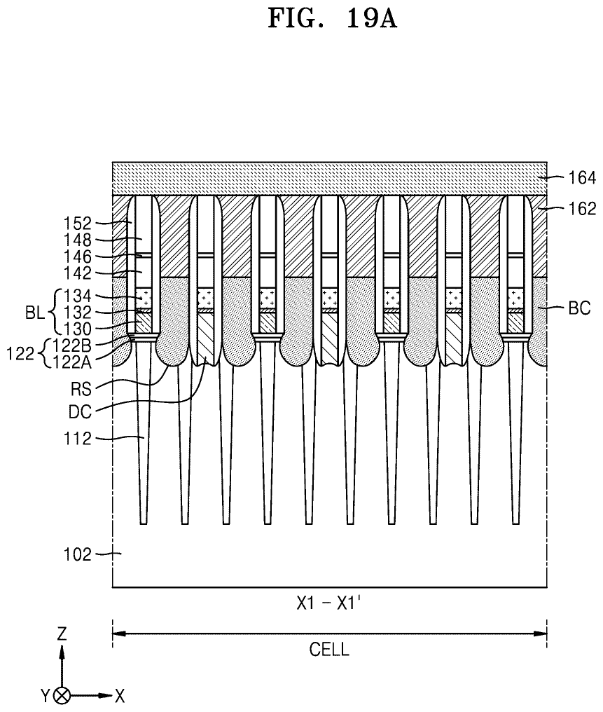

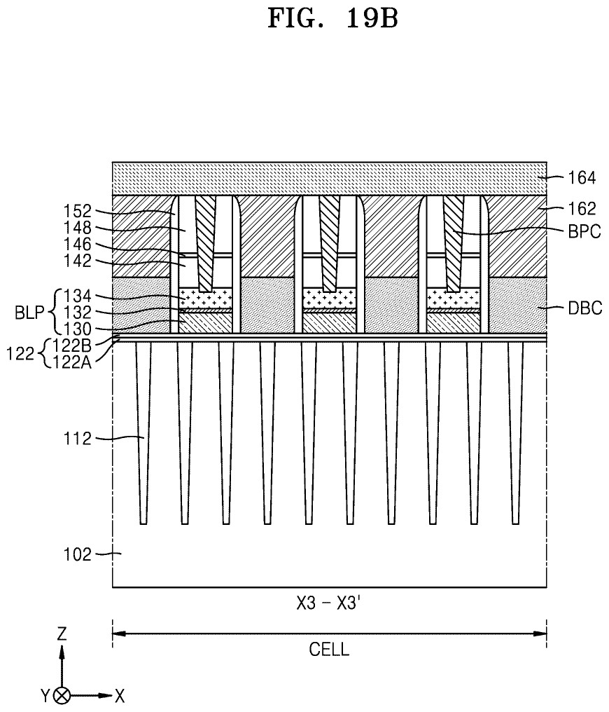

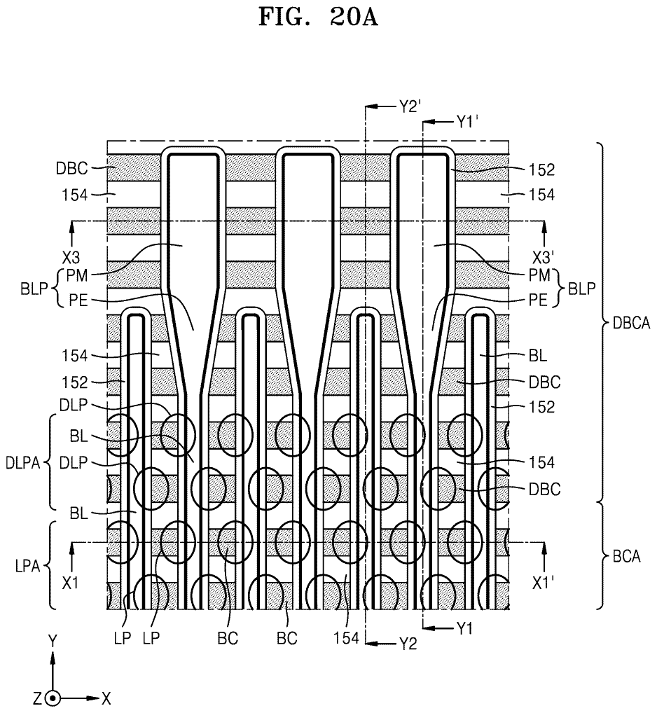

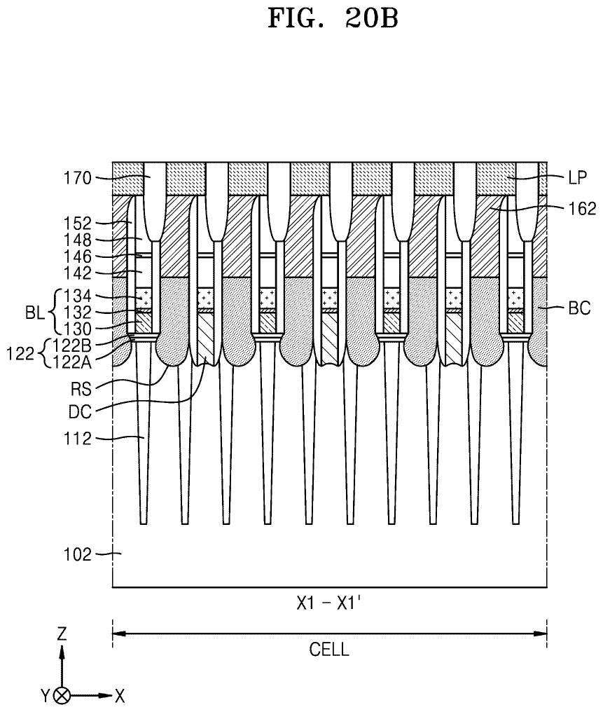

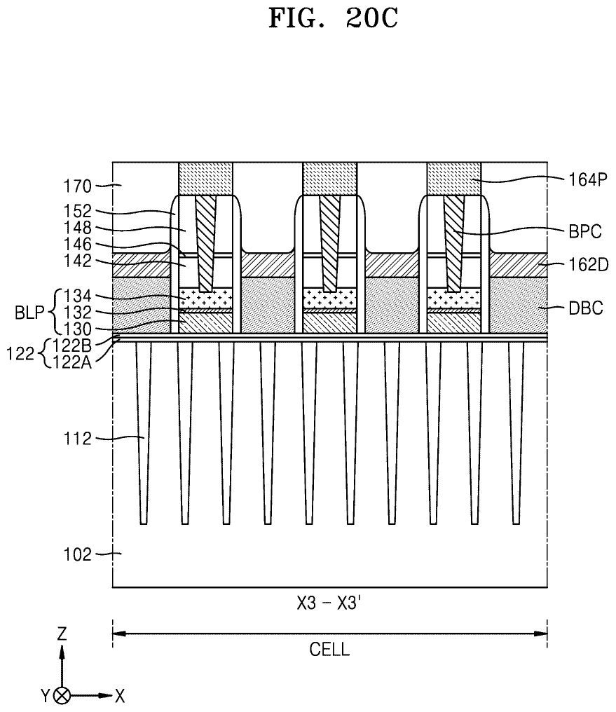

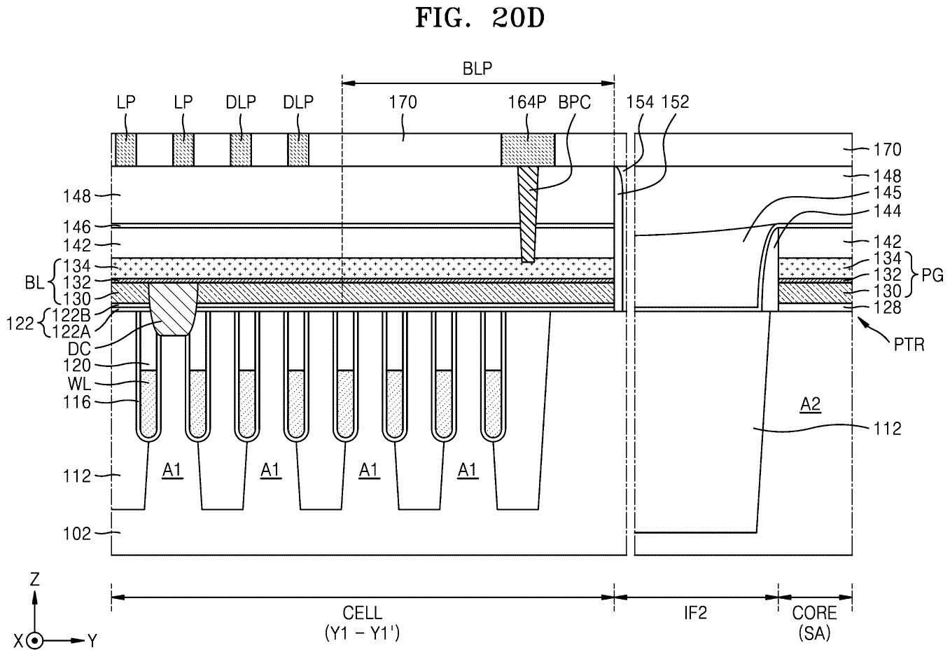

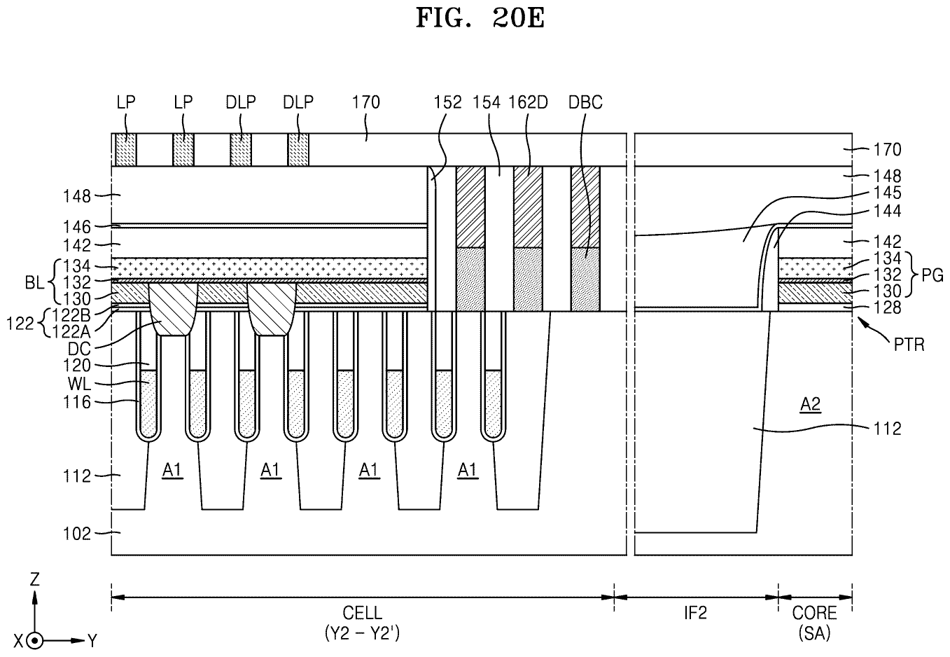

FIGS. 11A to 20E are diagrams respectively illustrating a sequence of processes of a method of fabricating an integrated circuit device, according to embodiments. More specifically, FIGS. 15A, 16A, 17A, 18A, and 20A are plan views of a region corresponding to the region EX2 of FIG. 2, according to the sequence of processes, FIGS. 11A, 12A, 13A, 14A, 15B, 16B, 18B, 19A, and 20B are cross-sectional views of a region corresponding to a cross-section taken along the line X1-X1′ of FIG. 4, according to the sequence of processes, FIGS. 11B, 12B, 13B, 14B, 15C, 16C, and 17B are cross-sectional views of a region corresponding to a cross-section taken along the line X2-X2′ of FIG. 4, according to the sequence of processes, FIGS. 15D, 16D, 17C, 18C, 19B, and 20C are cross-sectional views of a region corresponding to a cross-section taken along the line X3-X3′ of FIG. 4, according to the sequence of processes, FIGS. 11C, 13C, 14C, 15E, and 20D are cross-sectional views of a region corresponding to a cross-section taken along the line Y1-Y1′ of FIG. 4, according to the sequence of processes, and FIGS. 15F and 20E are cross-sectional views of a region corresponding to a cross-section taken along the line Y2-Y2′ of FIG. 4, according to the sequence of processes. An example of a method of fabricating the integrated circuit device 100 shown in FIGS. 3 to 5E is described with reference to FIGS. 11A to 20E. In FIGS. 11A to 20E, the same reference numerals as in FIGS. 3 to 5E respectively denote the same members, and here, repeated descriptions thereof are omitted.

Referring to FIGS. 11A, 11B, and 11C, a plurality of device isolation trenches T1 may be formed in the substrate 102, and a plurality of device isolation films 112 are formed to respectively fill the plurality of device isolation trenches T1, thereby defining a plurality of cell active regions A1 in the cell array area CELL of the substrate 102 and defining a peripheral active area A2 in the peripheral circuit area including the core area CORE.

A plurality of word line trenches may be formed in the substrate 102 in the cell array area CELL to extend parallel to each other, and then, a gate dielectric film 116, a word line WL, and a buried insulating film 120 may be sequentially formed in the stated order in each of the plurality of word line trenches. A plurality of source/drain regions may be respectively formed in upper portions of the plurality of cell active regions A1 by implanting impurity ions into portions of the plurality of cell active regions A1 on both sides of the plurality of word lines WL. In some embodiments, the plurality of source/drain regions may be formed before the plurality of word lines WL are formed.

Next, a buffer film 122 may be formed by forming a first insulating film 122A and a second insulating film 122B in the stated order on a main surface 102M of the substrate 102 in the cell array area CELL, and a gate dielectric film 128 may be formed on the main surface 102M of the substrate 102 in the peripheral circuit area including the core area CORE.

Referring to FIGS. 12A and 12B, a lower conductive layer 130 may be formed over the substrate 102 to cover the buffer film 122 and the gate dielectric film 128, followed by etching a portion of the lower conductive layer 130. Next, a portion of the substrate 102 and a portion of the device isolation film 112, which are exposed as a result of the etching, may be etched, thereby forming a plurality of direct contact holes DCH to expose the cell active region A1 of the substrate 102, and then, a plurality of direct contacts DC may be formed to respectively fill the plurality of direct contact holes DCH. In an example of a process of forming the plurality of direct contacts DC, a conductive layer may be formed in the plurality of direct contact holes DCH and on the lower conductive layer 130 to have a sufficient thickness to fill the direct contact hole DCH, and then, the conductive layer may be etched back such that the conductive layer remains only in the direct contact hole DCH. The conductive layer may include doped polysilicon, Ge, W, WN, Co, Ni, Al, Mo, Ru, Ti, TiN, Ta, TaN, Cu, or a combination thereof.

Referring to FIGS. 13A, 13B, and 13C, in each of the cell array area CELL and the peripheral circuit area that includes the core area CORE, an intermediate conductive layer 132, an upper conductive layer 134, and an insulating capping layer 142 may be formed in the stated order on the lower conductive layer 130 and the plurality of direct contacts DC, followed by patterning the insulating capping layer 142, the upper conductive layer 134, the intermediate conductive layer 132, the lower conductive layer 130, the buffer film 122, and the gate dielectric film 128, thereby forming a cell stack pattern in the cell array area CELL and forming a peripheral stack pattern in the peripheral circuit area including the core area CORE, the cell stack pattern including the buffer film 122, the lower conductive layer 130, the plurality of direct contacts DC, the intermediate conductive layer 132, the upper conductive layer 134, and the insulating capping layer 142, and the peripheral stack pattern including the gate dielectric film 128, the peripheral gate PG, and the insulating capping layer 142. Next, an insulating spacer 144 may be formed to cover the sidewall of each of the cell stack pattern and the peripheral stack pattern.

A plurality of peripheral transistors PTR may be formed in the peripheral circuit area including the core area CORE. To form the plurality of peripheral transistors PTR, a plurality of source/drain regions may be formed by implanting ions into the substrate 102 on both sides of the peripheral gate PG.

Referring to FIGS. 14A, 14B, and 14C, an insulating thin film 146 may be formed to conformally cover exposed surfaces of the resulting product having undergone the processes described with reference to FIGS. 13A, 13B, and 13C, followed by filling a recess space on the insulating thin film 146 with a gap-fill insulating film 145, and then, an upper insulating capping layer 148 may be formed on the insulating thin film 146 and the gap-fill insulating film 145 so as to have a flat upper surface.

Referring to FIGS. 15A, 15B, 15C, 15D, and 15E, in the cell array area CELL of the resulting product having undergone the processes described with reference to FIGS. 14A, 14B, and 14C, the cell stack pattern and both the insulating thin film 146 and the upper insulating capping layer 148 covering the cell stack pattern may be patterned, whereby a plurality of bit lines BL and a plurality of bit line pads BLP respectively and integrally connected to the plurality of bit lines BL may be formed, and a plurality of insulating spacers 152 may be formed to cover the respective sidewalls of the plurality of bit lines BL and the plurality of bit line pads BLP and the respective sidewalls of the insulating capping layer 142, the insulating thin film 146, and the upper insulating capping layer 148, which remain on the upper surface of each of the plurality of bit lines BL and the plurality of bit line pads BLP. After the plurality of insulating spacers 152 are formed, a line space LS may remain between each of the plurality of bit lines BL. The height of the upper insulating capping layer 148 may be reduced by accompanying etching processes while the plurality of bit lines BL and the plurality of insulating spacers 152 are being formed.

The buffer film 122, which is exposed by the line space LS between each of the plurality of bit lines BL, and a portion of the substrate 102 under the buffer film 122 may be etched, thereby forming a plurality of recess spaces RS to expose the cell active region A1. While the plurality of recess spaces RS are being formed, portions of the buried insulating film 120 may also be etched, thereby forming a plurality of recess spaces 120R in the upper surface of the buried insulating film 120.

Referring to FIGS. 16A, 16B, 16C, and 16D, a conductive layer BCL may be formed to fill the line space LS between each of the plurality of bit lines BL and spaces between each of the plurality of bit line pads BLP. The conductive layer BCL may have a line-type planar shape extending lengthwise in the second horizontal direction (the Y direction) in the line space LS (see FIGS. 15B and 15C) between each of the plurality of bit lines BL and in the spaces between each of the plurality of bit line pads BLP. The conductive layer BCL may include doped polysilicon.

Referring to FIGS. 17A, 17B, and 17C, in the resulting product of FIGS. 16A, 16B, 16C, and 16D, the conductive layer BCL may be patterned, thereby forming a plurality of buried contact patterns BCP from the conductive layer BCL. Next, in the line space LS (see FIGS. 15B and 15C) between each of the plurality of bit lines BL and in the spaces between each of the plurality of bit line pads BLP, an insulating fence 154 may fill a space between each of the plurality of buried contact patterns BCP. Next, a plurality of pad contact plugs BPC may be formed to pass through, in the vertical direction (the Z direction), the insulating capping layer 142, the insulating thin film 146, and the upper insulating capping layer 148 on each of the plurality of bit line pads BLP.

Referring to FIGS. 18A, 18B, and 18C, in the resulting product of FIGS. 17A, 17B, and 17C, each of the plurality of buried contact patterns BCP may be removed from the upper surface of each thereof by as much as a certain thickness, thereby forming a plurality of buried contacts BC and a plurality of dummy buried contacts DBC.

Referring to FIGS. 19A and 19B, a plurality of conductive contact plugs 162 may be formed to respectively cover the plurality of buried contacts BC in the line space LS (see FIGS. 15B and 15C) between each of the plurality of bit lines BL. While the plurality of conductive contact plugs 162 are being formed, the conductive contact plug 162 may also be formed on each of the plurality of dummy buried contacts DBC in the spaces between each of the plurality of bit line pads BLP.

Next, an upper conductive layer 164 may be formed to cover a resulting product in which the plurality of conductive contact plugs 162 are formed. The upper conductive layer 164 may be formed to contact each of the plurality of conductive contact plugs 162 and the plurality of buried contact patterns BCP. In some embodiments, the upper conductive layer 164 may include W.

Referring to FIGS. 20A, 20B, 20C, 20D, and 20E, in the resulting product having undergone the processes described with reference to FIGS. 19A and 19B, the upper conductive layer 164 may be patterned, thereby forming a plurality of conductive landing pads LP, a plurality of conductive dummy landing pads DLP, and a plurality of pad wiring layers 164P from the upper conductive layer 164. Next, a portion of each of the plurality of conductive contact plugs 162, and a portion of each of the plurality of upper insulating capping layers 148 and the plurality of insulating spacers 152, which respectively cover the plurality of bit lines BL, may be removed by etching portions of lower structures exposed as a result of patterning the upper conductive layer 164, thereby preparing isolation spaces. Next, an insulating film 170 may be formed to fill the isolation spaces and fill respective spaces between the plurality of conductive landing pads LP, the plurality of conductive dummy landing pads DLP, and the plurality of pad wiring layers 164P, thereby fabricating the integrated circuit device 100 shown in FIGS. 3 and 5E.

Heretofore, although the example of the method of fabricating the integrated circuit device 100 shown in FIGS. 3 to 5E has been described with reference to FIGS. 11A to 20E, it will be understood by those of ordinary skill in the art that, by making various modifications and changes to the example described with reference to FIGS. 11A to 20E without departing from the spirit and scope of the inventive concept, the integrated circuit devices 200, 300, 400, 500, and 600 shown in FIGS. 6 to 10 and integrated circuit devices having various structures modified and changed therefrom may be fabricated.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a substrate having a cell array area;
a first bit line and a second bit line, which are arranged over the substrate in the cell array area so as to be spaced apart from each other in a first horizontal direction, the first bit line and the second bit line extending in a second horizontal direction that is perpendicular to the first horizontal direction; and
a bit line pad arranged over the substrate in a first edge portion, in the second horizontal direction, of the cell array area and integrally connected to only the first bit line out of the first bit line and the second bit line, the bit line pad having a width that is greater in the first horizontal direction than a width of each of the first bit line and the second bit line,
wherein the second bit line comprises a bit line extension portion facing the bit line pad in the first horizontal direction in the first edge portion of the cell array area.

2. The integrated circuit device of claim 1, further comprising:
a plurality of conductive landing pads arranged at a first vertical level over the first and second bit lines to overlap the first and second bit lines in a vertical direction; and
a conductive dummy structure arranged at the first vertical level over the first and second bit lines so as to be closer to the bit line pad in the second horizontal direction than the plurality of conductive landing pads,
wherein the bit line extension portion of the second bit line is closer to the first edge portion of the cell array area than the conductive dummy structure.

3. The integrated circuit device of claim 2, wherein the conductive dummy structure is arranged not to overlap the bit line extension portion in the vertical direction.

4. The integrated circuit device of claim 2, wherein the conductive dummy structure comprises a plurality of conductive dummy landing pads arranged to overlap the first and second bit lines in the vertical direction, and
the plurality of conductive landing pads and the plurality of conductive dummy landing pads comprise a same material.

5. The integrated circuit device of claim 2, wherein the conductive dummy structure comprises a single conductive dummy landing plate dam arranged to overlap the first and second bit lines in the vertical direction, and
the plurality of conductive landing pads and the conductive dummy landing plate dam comprise a same material.

6. The integrated circuit device of claim 1, wherein the bit line pad comprises a pad connection portion and a main pad portion, the pad connection portion having an increasing width in the first horizontal direction with an increasing distance from the first bit line, and the main pad portion being spaced apart from the first bit line in the second horizontal direction with the pad connection portion therebetween and having a second width that is greater in the first horizontal direction than a first width of the first bit line, and
the bit line extension portion of the second bit line comprises a portion facing the pad connection portion in the first horizontal direction.

7. The integrated circuit device of claim 1, wherein the bit line pad is located apart from the bit line extension portion of the second bit line in the first horizontal direction such that the bit line pad is not arranged on an extension line, in the second horizontal direction, of the second bit line.

8. The integrated circuit device of claim 1, wherein a planar shape of the bit line pad is symmetric about an extension line of the first bit line in the second horizontal direction.

9. The integrated circuit device of claim 1, wherein a planar shape of the bit line pad is asymmetric about an extension line of the first bit line in the second horizontal direction.

10. The integrated circuit device of claim 1, further comprising:
a plurality of buried contacts arranged in a line in the second horizontal direction between the first bit line and the second bit line; and
at least one dummy buried contact arranged on an extension line, which follows the second horizontal direction, of the second bit line and facing the bit line pad in the first horizontal direction,
wherein the plurality of buried contacts and the at least one dummy buried contact comprise a same material.

11. The integrated circuit device of claim 1, further comprising:
a plurality of buried contacts arranged in a line in the second horizontal direction between the first bit line and the second bit line; and
a plurality of dummy buried contacts arranged on an extension line, which follows the second horizontal direction, of the second bit line and facing the bit line pad in the first horizontal direction,
wherein, in the second horizontal direction, a first separation distance between two buried contacts selected among the plurality of buried contacts is equal to a second separation distance between two dummy buried contacts selected among the plurality of dummy buried contacts.

12. An integrated circuit device comprising:
a substrate that has a cell array area and a core area surrounding the cell array area;
a plurality of bit lines, which are arranged over the substrate in the cell array area so as to be spaced apart from each other in a first horizontal direction, the plurality of bit lines extending in a second horizontal direction that is perpendicular to the first horizontal direction; and
a plurality of bit line pads arranged over the substrate in the cell array area and respectively and integrally connected to the plurality of bit lines,
wherein the plurality of bit line pads comprise a plurality of first bit line pads that are arranged in a first edge portion, which is adjacent to the core area in the second horizontal direction, of the cell array area and respectively and integrally connected to only a plurality of first bit lines selected from among the plurality of bit lines every other bit line in the first horizontal direction, each of the plurality of first bit line pads having a width that is greater in the first horizontal direction than a width of each of the plurality of bit lines, and
a plurality of second bit lines except for the plurality of first bit lines from among the plurality of bit lines each comprise a bit line extension portion facing, in the first horizontal direction, two adjacent first bit line pads from among the plurality of first bit line pads in the first edge portion of the cell array area.

13. The integrated circuit device of claim 12, further comprising:
a plurality of conductive landing pads arranged at a first vertical level over the plurality of bit lines to overlap the plurality of bit lines in a vertical direction; and
a conductive dummy structure arranged at the first vertical level over the plurality of bit lines so as to be closer to the plurality of first bit line pads in the second horizontal direction than the plurality of conductive landing pads,
wherein the bit line extension portion of each of the plurality of second bit lines is closer to the first edge portion of the cell array area than the conductive dummy structure, and
wherein the conductive dummy structure is arranged not to overlap the bit line extension portion of each of the plurality of second bit lines in the vertical direction.

14. The integrated circuit device of claim 13, wherein the plurality of conductive landing pads and the conductive dummy structure comprise a same material.

15. The integrated circuit device of claim 12, wherein each of the plurality of first bit line pads comprises a pad connection portion and a main pad portion, the pad connection portion having an increasing width in the first horizontal direction with an increasing distance from one first bit line selected from the plurality of first bit lines, and the main pad portion being spaced apart from the selected one first bit line in the second horizontal direction with the pad connection portion therebetween and having a second width that is greater in the first horizontal direction than a first width of the selected one first bit line, and
the bit line extension portion of each of the plurality of second bit lines comprises a portion facing the pad connection portion of each of the plurality of first bit line pads in the first horizontal direction.

16. The integrated circuit device of claim 12, wherein each of the plurality of first bit line pads is located apart from, in the first horizontal direction, the bit line extension portion of a second bit line adjacent thereto from among the plurality of second bit lines such that each of the plurality of first bit line pads is not arranged on an extension line, in the second horizontal direction, of each of the plurality of first bit lines.

17. The integrated circuit device of claim 12, wherein a planar shape of each of the plurality of first bit line pads is symmetric about an extension line, in the second horizontal direction, of a first bit line corresponding to each of the plurality of first bit line pads from among the plurality of first bit lines.

18. The integrated circuit device of claim 12, wherein a planar shape of each of the plurality of first bit line pads is asymmetric about an extension line, in the second horizontal direction, of a first bit line corresponding to each of the plurality of first bit line pads from among the plurality of first bit lines.

19. The integrated circuit device of claim 12, further comprising:
a plurality of buried contacts arranged in a line in the second horizontal direction between each of the plurality of bit lines; and
a plurality of dummy buried contacts arranged in a line in the second horizontal direction between each of the plurality of first bit line pads,
wherein the plurality of buried contacts and the plurality of dummy buried contacts are arranged at equal intervals in the second horizontal direction, and
the plurality of buried contacts and the plurality of dummy buried contacts comprise a same material.

20. An integrated circuit device comprising:
a substrate, which has a cell array area, a peripheral circuit area including a core area adjacent to the cell array area, and an interface area between the cell array area and the core area;
a plurality of bit lines arranged over the substrate in the cell array area so as to be spaced apart from each other in a first horizontal direction, the plurality of bit lines extending in a second horizontal direction that is perpendicular to the first horizontal direction;
a plurality of bit line pads respectively and integrally connected to only a plurality of first bit lines arranged over the substrate in a first edge portion, which is adjacent to the core area, of the cell array area, the plurality of first bit lines being selected from among the plurality of bit lines every other bit line in the first horizontal direction;
a plurality of buried contacts arranged in a line in the second horizontal direction between each of the plurality of bit lines; and
a plurality of dummy buried contacts arranged in a line in the second horizontal direction between each of the plurality of bit line pads,
wherein each of the plurality of bit line pads has a width that is greater in the first horizontal direction than a width of each of the plurality of bit lines,
wherein a plurality of second bit lines except for the plurality of first bit lines from among the plurality of bit lines each comprise a bit line extension portion arranged between two adjacent bit line pads from among the plurality of bit line pads in the first edge portion of the cell array area,
wherein the plurality of buried contacts and the plurality of dummy buried contacts are arranged at equal pitches in the second horizontal direction, and
wherein the plurality of buried contacts and the plurality of dummy buried contacts comprise a same material.
